(19) United States
(12) Patent Application Publication
(10) Pub. No.: US 2025/0019623 A1
(43) Pub. Date: Jan. 16, 2025

(54) CLEANING COMPOSITION AND METHOD FOR MANUFACTURING SEMICONDUCTOR SUBSTRATE

(71) Applicant: FUJIFILM Corporation, Tokyo (JP)

(72) Inventors: Tetsuya KAMIMURA, Shizuoka (JP); Shimpei YAMADA, Shizuoka (JP)

(73) Assignee: FUJIFILM Corporation, Tokyo (JP)

(21) Appl. No.: 18/892,835

(22) Filed: Sep. 23, 2024

Related U.S. Application Data
(63) Continuation of application No. PCT/JP2023/009360, filed on Mar. 10, 2023.

(30) Foreign Application Priority Data
Mar. 28, 2022 (JP) 2022-052034
Oct. 12, 2022 (JP) 2022-163709

(51) Int. Cl. C11D 7/26; C11D 7/32; H01L 21/02

(52) U.S. Cl. CPC C11D 7/265; C11D 7/3218; C11D 7/3272; H01L 21/02074

(57) ABSTRACT

An object of the present invention is to provide a cleaning composition that suppresses a surface roughness of a region including Mo and has excellent removability of Mo-based residues in a case of being used in a treatment of an Mo-containing substrate. The cleaning composition of an embodiment of the present invention is a cleaning composition used in a treatment of a molybdenum-containing substrate, the cleaning composition including an organic acid and organic amine compounds having at least one group selected from the group consisting of a primary amino group, a secondary amino group, and a tertiary amino group, in which the cleaning composition includes two or more kinds of the organic amine compounds.

### CROSS-REFERENCE TO RELATED APPLICATIONS

This application is a Continuation of PCT International Application No. PCT/JP2023/009360 filed on Mar. 10, 2023, which claims priority under 35 U.S.C. § 119 (a) to Japanese Patent Application No. 2022-052034 filed on Mar. 28, 2022 and Japanese Patent Application No. 2022-163709 filed on Oct. 12, 2022. The above applications are hereby expressly incorporated by reference, in their entirety, into the present application.

### BACKGROUND OF THE INVENTION

### 1. Field of the Invention

The present invention relates to a cleaning composition and a method for manufacturing a semiconductor substrate.

### 2. Description of the Related Art

In recent years, in the field of semiconductors, with a remarkable increase in integration and performance, even a very small amount of impurities (contamination) or deposits (particles) has a great influence on the performance of a device and eventually the yield of a product. In the field of semiconductors, it is general to perform cleaning with a cleaning liquid in order to reduce the influence of contamination and particles in the manufacture.

On the semiconductor substrate, various contaminations and particles (hereinafter also referred to as residues) may be generated in each manufacturing step for a semiconductor element. Examples thereof include residues obtained by a photolithography step or a dry etching step, and residues obtained by a chemical mechanical polishing (CMP) treatment.

As a cleaning composition for performing the removal of such residues, for example, JP2020-155568A discloses a post-CMP cleaning agent (cleaning composition) including an antibacterial agent and a carboxy group-containing amine compound.

### SUMMARY OF THE INVENTION

In recent years, molybdenum (Mo) may be used in the manufacture of a semiconductor element, and an Mo-containing substrate may be an object to be cleaned. In the Mo-containing substrate, a residue including Mo (Mo-based residue) may be present on the substrate.

The present inventors have applied the cleaning agent (cleaning composition) described in JP2020-155568A to an Mo-containing substrate, and as a result, the removability of the Mo-based residues was not sufficient and there was room for improvement.

In addition, even in a case where the cleaning is performed with the cleaning composition, it is preferable that the corrosion or the like of Mo in the Mo-containing substrate should be suppressed and the surface roughness should not occur.

Here, the present inventors have found that in a case where the cleaning agent (cleaning composition) described in JP2020-155568A is applied to an Mo-containing substrate, a surface roughness is likely to occur in a region where Mo in the Mo-containing substrate is present (region including Mo), and there is room for improvement.

Therefore, an object of the present invention is to provide a cleaning composition that suppresses a surface roughness of a region including Mo and has excellent removability of Mo-based residues in a case of being used in a treatment of an Mo-containing substrate.

In addition, another object of the present invention is to provide a method for manufacturing a semiconductor substrate, using the cleaning composition.

The present inventors conducted a thorough investigation to accomplish the objects, thereby completing the present invention. That is, the present inventors have found that the objects can be accomplished by the following configurations.
[1] A cleaning composition used in a treatment of a molybdenum-containing substrate, the cleaning composition comprising:
an organic acid; and
organic amine compounds having at least one group selected from the group consisting of a primary amino group, a secondary amino group, and a tertiary amino group,
in which the cleaning composition includes two or more kinds of the organic amine compounds.
[2] The cleaning composition according to [1],
in which the cleaning composition has a pH of 2 to 9.
[3] The cleaning composition according to [1] or [2],
in which the cleaning composition has a pH of 3 to 8.
[4] The cleaning composition according to any one of [1] to [3],
in which the two or more kinds of the organic amine compounds include an amino alcohol.
[5] The cleaning composition according to any one of [1] to [4],
in which the two or more kinds of the organic amine compounds include an amino acid.
[6] The cleaning composition according to [5],
in which a mass ratio of a content of the organic acid to a content of the amino acid is 2.0 to 210.0.
[7] The cleaning composition according to any one of [1] to [6],
in which the cleaning composition includes two or more kinds of the organic acids.
[8] The cleaning composition according to any one of [1] to [7],
in which the organic acid includes one or more kinds of organic acids X selected from the group consisting of an aliphatic monocarboxylic acid, an aliphatic polycarboxylic acid, and an aliphatic hydroxycarboxylic acid.
[9] The cleaning composition according to [8],
in which the organic acids X include one or more kinds of compounds selected from the group consisting of propionic acid, oxalic acid, malonic acid, succinic acid, adipic acid, glucuronic acid, glycolic acid, lactic acid, malic acid, tartaric acid, citric acid, and gluconic acid.
[10] The cleaning composition described in any one of [1] to [9],
in which the organic acid includes one or more kinds of organic acids Y selected from the group consisting of a compound represented by Formula (Y1) and a high-molecular-weight compound having an acid group.

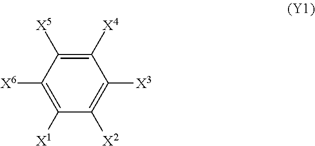

In Formula (Y1), X¹ represents an acid group.

In Formula (Y1), X² to X⁶ each independently represent a hydrogen atom or a substituent, and at least one of X², . . . , or X⁶ represents a hydrophilic group.
[11] The cleaning composition according to any one of [1] to [10],
in which the organic acid has a molecular weight of 5,000 or less.
[12] The cleaning composition according to any one of [1] to [11],
in which a mass ratio of a content of the organic acid to a total content of the organic amine compounds is 0.10 to 6.20.
[13] The cleaning composition according to any one of [1] to [12], further comprising:
an antibacterial agent.
[14] The cleaning composition according to [13],
in which a mass ratio of a total content of the organic amine compounds to a content of the antibacterial agent is 0.1 to 200.0.
[15] The cleaning composition according to or [14],
in which the organic amine compounds include an amino acid, and
a mass ratio of a content of the amino acid to a content of the antibacterial agent is 0.1 to 200.0.
[16] The cleaning composition according to any one of [1] to [15],
in which the cleaning composition has a surface tension of 65 to 75 mN/m.
[17] The cleaning composition according to any one of [1] to [16],
in which the cleaning composition is used in a treatment of the molybdenum-containing substrate which has been subjected to a chemical mechanical polishing treatment.
[18] The cleaning composition according to any one of [1] to [17],
in which the molybdenum-containing substrate further includes a material selected from the group consisting of silicon, silicon nitride, silicon oxide, silicon oxynitride, carbon-containing silicon oxide, and silicon carbide.
[19] A method for manufacturing a semiconductor substrate, comprising:
a step of cleaning a molybdenum-containing substrate, using the cleaning composition according to any one of [1] to [18].

According to the present invention, it is possible to provide a cleaning composition that suppresses a surface roughness of a region including Mo and has excellent removability of Mo-based residues in a case of being used in a treatment of an Mo-containing substrate.

In addition, according to the present invention, it is also possible to provide a method for manufacturing a semiconductor substrate, the method using the cleaning composition.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

Hereinafter, the meaning of each description in the present specification will be described.

In the present specification, a numerical range represented by “to” means a range including numerical values before and after “to” as a lower limit value and an upper limit value.

The compounds described in the present specification may include isomers (compounds having the same number of atoms but having different structures), optical isomers, and isotopes thereof unless otherwise specified. In addition, only one kind or plural kinds of the isomers and the isotopes may be included.

### <Cleaning Composition>

The cleaning composition of an embodiment of the present invention is a cleaning composition used in a treatment of a molybdenum-containing substrate, the cleaning composition including an organic acid and organic amine compounds having at least one group selected from the group consisting of a primary amino group, a secondary amino group, and a tertiary amino group, in which the cleaning composition includes two or more kinds of the organic amine compounds.

In a case where the cleaning composition is used in a treatment of an Mo-containing substrate, a mechanism by which the surface roughness of a region including Mo is suppressed and the removability of Mo-based residues is excellent is not always clear, but is presumed to be as follows by the present inventors.

Since the cleaning composition of the embodiment of the present invention includes an organic acid, a surface of the Mo-based residues can be dissolved, and the cleaning composition of the embodiment of the present invention thus has excellent removability of the Mo-based residues. On the other hand, two or more kinds of the organic amine compounds included in the cleaning composition of the embodiment of the present invention are easily adsorbed on a surface of the region including Mo, and the effect of the organic acid can be adjusted to an appropriate degree by interacting with the organic acid. Thus, the surface roughness of the region including Mo can be suppressed. As a result, it is considered that the cleaning composition of the embodiment of the present invention suppresses the surface roughness of the region including Mo and has excellent removability of the Mo-based residues.

Hereinafter, the components included in the cleaning composition of the embodiment of the present invention will be described.

Furthermore, in a case of a use in the treatment of the Mo-containing substrate, a case where the surface roughness of the region including Mo can be suppressed will hereinafter also be simply referred as “the surface roughness can be suppressed”.

In addition, in a case of a use in the treatment of the Mo-containing substrate, a case where the polymer has excellent removability of the Mo-based residues will hereinafter also be simply referred to as “the removability of residues is excellent”.

### [Organic Acid]

The cleaning composition of the embodiment of the present invention includes an organic acid.

The organic acid refers to an organic compound that exhibits acidity in a case where the compound is dissolved in water to form an aqueous solution thereof. An acid dissociation constant (pKa) of the organic acid is preferably 10.0 or less, and more preferably 5.0 or less. The lower limit of the acid dissociation constant of the organic acid is −2.0 or more, and preferably 0.0 or more.

Examples of the organic acid include an organic compound having an acid group, and examples of the acid group include a carboxy group, a sulfo group, and a phosphonic acid group.

That is, examples of the organic acid include a carboxylic acid having a carboxy group, a sulfonic acid having a sulfo group, and a phosphonic acid having a phosphonic acid group. Among these, the carboxylic acid or the sulfonic acid is preferable, and the carboxylic acid is more preferable.

Furthermore, the compound corresponding to an organic amine compound which will be described later is taken as the organic amine compound, and is not included in the organic acid.

The cleaning composition preferably includes two or more kinds of organic acids. Among these, the cleaning composition preferably includes at least one of the organic acid X or the organic acid Y, which will be described in the latter part, and more preferably includes the organic acid X and the organic acid Y.

### (Organic Acid X)

The organic acid X is preferably an aliphatic carboxylic acid having one or more carboxy groups in the molecule and not having an aromatic ring in a molecular skeleton thereof.

It is considered that the cleaning composition has more excellent removability of residues by including the organic acid X.

Furthermore, in a case where the organic acid X also corresponds to an amino acid which will be described later, it is included in the amino acid which will be described later and not included in the organic acid X.

The number of carboxy groups contained in the organic acid X may be 1, or 2 or more. That is, the organic acid may be an aliphatic monocarboxylic acid or an aliphatic polycarboxylic acid. In the aliphatic polycarboxylic acid, the upper limit of the number of carboxy groups is, for example, 5 or less, and is more preferably 4 or less, and still more preferably 3 or less.

In addition, the organic acid X may have a substituent other than a carboxy group. As the substituent contained in the organic acid X, a hydroxy group is preferable. That is, the organic acid X may be an aliphatic hydroxycarboxylic acid. The aliphatic hydroxycarboxylic acid may be an aliphatic hydroxymonocarboxylic acid or an aliphatic hydroxypolycarboxylic acid. The number of hydroxy groups contained in the aliphatic hydroxycarboxylic acid is 1 or more, and preferably 6 or less.

In addition, the aliphatic group contained in the aliphatic carboxylic acid may have a cyclic structure.

As the aliphatic monocarboxylic acid, a compound represented by Formula (X1) is preferable.

R^{X1}—COOH (X1)

In Formula (X1), R^{X1} represents an alkyl group having 1 to 6 carbon atoms. The alkyl group represented by R^{X1} may be linear or branched, and may have a cyclic structure. The methylene group constituting the alkyl group represented by R^{X1} may be substituted with —O—.

Examples of the alkyl group represented by R^{X1} include a methyl group, an ethyl group, a propyl group, an isopropyl group, a butyl group, and a cyclohexyl group.

Examples of the compound represented by Formula (X1) include acetic acid, propionic acid, butyric acid, isobutyric acid, valeric acid, and cyclohexanecarboxylic acid.

As the aliphatic polycarboxylic acid, a compound represented by Formula (X2) is preferable.

HOOC—R^{X2}—COOH (X2)

In Formula (X2), R^{X2} represents a single bond or an alkylene group having 1 to 6 carbon atoms. The alkylene group represented by R^{X2} may be linear or branched, and may have a cyclic structure. The methylene group constituting the alkylene group represented by R^{X2} may be substituted with —O—. The hydrogen atom in the alkyl group represented by R^{X2} may be substituted with a carboxy group.

Examples of the alkylene group represented by R^{X2} include a methylene group, an ethylene group, a propylene group, a butylene group, and a cyclohexylene group.

Examples of the compound represented by Formula (X2) include oxalic acid, malonic acid, succinic acid, glutaric acid, adipic acid, and cyclohexanedicarboxylic acid.

As the aliphatic hydroxy monocarboxylic acid, a compound represented by Formula (X3) is preferable.

R^{X3}—COOH (X3)

In Formula (X3), R^{X3} represents an alkyl group having 1 to 6 carbon atoms, which has a hydroxy group. The alkyl group having a hydroxy group, represented by R^{X3}, may be linear or branched, and may have a cyclic structure. The methylene group constituting the alkyl group having a hydroxy group, represented by R^{X3}, may be substituted with —O—. Examples of the alkyl group having a hydroxy group, represented by R^{X3}, include a group in which one or more hydrogen atoms of the alkyl group represented by R^{X1} are substituted with hydroxy groups.

Examples of the compound represented by Formula (X3) include glycolic acid, lactic acid, glyceric acid, hydroxybutyric acid, gluconic acid, and glucuronic acid.

As the aliphatic hydroxypolycarboxylic acid, a compound represented by Formula (X4) is preferable.

HOOC—R^{X4}—COOH (X4)

In Formula (X4), R^{X4} represents an alkylene group having 1 to 6 carbon atoms, which has a hydroxy group. The alkylene group having a hydroxy group, represented by R^{X4}, may be linear or branched, and may have a cyclic structure. The methylene group constituting the alkylene group having a hydroxy group, represented by R^{X4}, may be substituted with —O—. The hydrogen atom in the alkyl group having a hydroxy group, represented by R^{X4}, may be substituted with a carboxy group.

Examples of the alkylene group having a hydroxy group, represented by R^{X4}, include a group in which one or more hydrogen atoms of the alkylene group represented by R^{X2} are substituted with hydroxy groups.

Examples of the compound represented by Formula (X4) include tartronic acid, malic acid, tartaric acid, and citric acid.

As the aliphatic carboxylic acid, that is, the organic acid X, the aliphatic monocarboxylic acid, the aliphatic polycarboxylic acid, or the aliphatic hydroxycarboxylic acid is preferable. Preferred examples of the organic acid X include one or more kinds of compounds selected from the group consisting of propionic acid, oxalic acid, malonic acid, succinic acid, adipic acid, gluconic acid, glycolic acid, lactic acid, malic acid, tartaric acid, citric acid, and gluconic acid. Among these, as the organic acid X, citric acid is particularly preferable.

The aliphatic carboxylic acid, that is, the organic acid X is also preferably an organic acid X having an antibacterial action. Furthermore, the antibacterial action refers to an action of suppressing a growth of microorganisms. Hereinafter, the organic acid X having an antibacterial action will also be referred to as an organic acid XA.

Examples of the organic acid XA include sorbic acid.

A content of the organic acid XA is preferably 0.01% to 2.0% by mass, and more preferably 0.01% to 1.0% by mass with respect to the total mass of the cleaning composition.

A content of the organic acid X is preferably 0.01% to 15.0% by mass, more preferably 0.1% to 10.0% by mass, and still more preferably 0.4% to 4.0% by mass with respect to the total mass of the cleaning composition.

The organic acid X may be used alone or in combination of two or more kinds thereof. In a case where two or more kinds of the organic acids X are used in combination, it is also preferable that at least one of the organic acids X is the organic acid XA. In a case where two or more kinds of the organic acids X are used, a total content thereof is also preferably within the preferred range.

In a case where the organic acid X includes the organic acid XA, a ratio of the content of the organic acid XA to a total content of the organic acid X is preferably 0.01 to 0.3, and more preferably 0.02 to 0.1.

### (Organic Acid Y)

The organic acid Y is preferably one or more kinds of organic acids selected from the group consisting of an aromatic organic acid having an aromatic ring (hereinafter also referred to as an “aromatic organic acid”) and a high-molecular-weight compound having an acid group (hereinafter also referred to as a “high-molecular-weight organic acid”).

It is considered that the cleaning composition including the organic acid Y is more excellent due to the removability of residues.

Hereinafter, the aromatic organic acid and the high-molecular-weight organic acid will be described.

The aromatic organic acid refers to a compound having an aromatic ring and an acid group. Examples of the acid group include a carboxy group, a sulfo group, and a phosphonic acid group, and the carboxy group is preferable.

As the aromatic organic acid, a compound represented by Formula (Y1) is preferable.

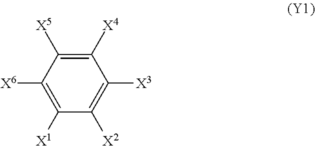

In Formula (Y1), X¹ represents an acid group. Examples of the acid group represented by X¹ include a carboxy group, a sulfo group, and a phosphonic acid group, and the carboxy group is preferable.

In Formula (Y1), X² to X⁶ each independently represent a hydrogen atom or a substituent, and at least one of X², . . . , or X⁶ represents a hydrophilic group. Examples of the substituent include a halogen atom, an alkyl group, an alkoxy group, an alkylcarbonyloxy group, a thiol group, and a hydrophilic group. Examples of the hydrophilic group include a hydroxy group and the acid groups.

The alkyl group contained in the alkyl group, the alkoxy group, and the alkylcarbonyloxy group may be linear or branched. The alkyl group contained in the groups preferably has 1 to 6 carbon atoms, and more preferably has 1 to 3 carbon atoms.

Examples of the compound represented by Formula (Y1) include phthalic acid, terephthalic acid, trimellitic acid (benzene-1,2,4-tricarboxylic acid), trimellitic acid (benzene-1,3,5-tricarboxylic acid), pyromellitic acid (benzene-1,2,4,5-tetracarboxylic acid), mellitic acid (benzenehexacarboxylic acid), salicylic acid, gallic acid, anisic acid (methoxybenzoic acid), and hydroxybenzenesulfonic acid.

Among those, from the viewpoint that the removability of residues is more excellent, phthalic acid, trimellitic acid, or pyromellitic acid is preferable as the aromatic organic acid.

Examples of the aromatic organic acid also include an aromatic organic acid having an antibacterial action. Hereinafter, the aromatic organic acid having an antibacterial action is also referred to as an antibacterial aromatic organic acid A.

Examples of the antibacterial aromatic organic acid A include benzoic acid, salicylic acid, and salts thereof.

A content of the antibacterial aromatic organic acid A is preferably 0.001% to 2.0% by mass, and more preferably 0.01% to 1.0% by mass with respect to the total mass of the cleaning composition.

The high-molecular-weight organic acid refers to a high-molecular-weight compound having repeating units having an acid group. Examples of the acid group include a carboxy group, a sulfo group, and a phosphonic acid group, and the carboxy group is preferable.

As the repeating unit having an acid group included in the high-molecular-weight organic acid, a repeating unit represented by Formula (Y2) is preferable.

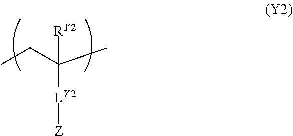

In Formula (Y2), R^{Y2} represents a hydrogen atom or an alkyl group. The alkyl group represented by R^{Y2} preferably has 1 to 3 carbon atoms, and more preferably has 1 carbon atom. Examples of the alkyl group represented by R^{Y2} include a methyl group, an ethyl group, and a propyl group.

In Formula (Y2), L^{Y2} represents a single bond or a divalent linking group. Examples of the divalent linking group include an alkylene group, an arylene group, —O—, —CO—, and a divalent linking group formed by a combination thereof.

The alkylene group represented by L^{Y2} preferably has 1 to 3 carbon atoms. Examples of the divalent alkylene group represented by L12 include a methylene group, an ethylene group, and a propylene group.

The arylene group represented by L^{Y2} is preferably the phenylene group.

In Formula (Y2), Z represents an acid group. Examples of the acid group include a carboxy group, a sulfo group, and a phosphonic acid group, and the carboxy group or the sulfo group is preferable.

Examples of the repeating unit represented by Formula (Y2) include a repeating unit derived from acrylic acid, a repeating unit derived from methacrylic acid, a repeating unit derived from vinylphosphonic acid, a repeating unit derived from vinylsulfonic acid, a repeating unit derived from 4-vinylbenzoic acid, a repeating unit derived from 4-styrenesulfonic acid, and a repeating unit derived from 4-styrenephosphonic acid.

The high-molecular-weight organic acid may be a copolymer having two or more kinds of repeating units. In a case where the high-molecular-weight organic acid is a copolymer, it may have two or more kinds of repeating units represented by Formula (Y2) or may have a repeating unit other than the repeating unit represented by Formula (Y2).

Examples of the repeating unit other than the repeating unit represented by Formula (Y2) include repeating units based on crotonic acid, itaconic acid, maleic acid, fumaric acid, citraconic acid, 2-methacryloyloxymethylsuccinic acid, β-carboxyethyl acrylate, and salts thereof.

The repeating unit other than the repeating unit represented by Formula (Y2) may be a repeating unit obtained by a reaction with the repeating unit represented by Formula (Y2). Examples of such a repeating unit include a repeating unit obtained by a reaction of the repeating unit represented by Formula (Y2) with polyalkylene glycol.

In a case where the high-molecular-weight organic acid has the repeating unit represented by Formula (Y2), a content of the repeating unit represented by Formula (Y2) is preferably 30% by mole or more, and more preferably 50% by mole or more with respect to all the repeating units of the high-molecular-weight organic acid. An upper limit thereof is not particularly limited and may be 100% by mole.

Furthermore, the high-molecular-weight organic acid can be synthesized according to an ordinary method.

A content of the organic acid Y is preferably 0.001% to 10.0% by mass, more preferably 0.01% to 5.0% by mass, and still more preferably 0.03% to 1.0% by mass with respect to the total mass of the cleaning composition.

The organic acid Y may be used alone or in combination of two or more kinds thereof. In a case where two or more kinds of the organic acids Y are used, it is also preferable that a total content thereof is in the preferred ranges.

In a case where the organic acid Y includes an antibacterial aromatic organic acid A, a ratio of the content of the antibacterial aromatic organic acid A to a total content of the organic acids Y is preferably 0.01 to 2.0, and more preferably 0.1 to 1.0.

### (Other Organic Acids)

The organic acid may include other organic acids different from the organic acid X and the organic acid Y.

Examples of such other organic acids include an organic acid having an antibacterial action. Hereinafter, such other organic acids having an antibacterial action will also be referred to as the antibacterial organic acid A.

Examples of the antibacterial organic acid A include an enol-based compound and a phenol-based compound.

Examples of the enol-based compound include dehydroacetic acid and a salt thereof.

Examples of the phenol-based compound include 3-methyl-4-chlorophenol (PCMC), 3-methyl-4-isopropylphenol (BIOSOL), 4-chloro-3,5-dimethylphenol (PCMX), cresol, chlorothymol, dichloroxylenol, hexachlorophene, and ethyl parahydroxybenzoate ester (ethylparaben). Among these, cresol is preferable.

A content of the antibacterial organic acid A is preferably 0.01% to 2.0% by mass, and more preferably 0.01% to 1.0% by mass with respect to the total mass of the cleaning composition.

As such other organic acids, a phosphonic acid A having a phosphonic acid group is also preferable.

As the phosphonic acid A, a compound represented by General Formula (I) is preferable.

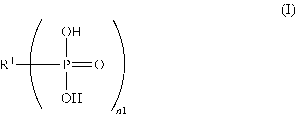

In General Formula (I), n1 represents an integer of 1 to 4.

In a case where n1 is 1, in General Formula (I), R¹ represents an alkyl group having 1 to 8 carbon atoms, an alkynyl group, a cycloalkyl group, an aryl group, or a group formed by a combination of two or more of these groups. The groups may each have a substituent.

The alkyl group having 1 to 8 carbon atoms may be linear or branched. Examples of the alkyl group having 1 to 8 carbon atoms include a methyl group, an ethyl group, a propyl group, a butyl group, a pentyl group, a hexyl group, a heptyl group, and an octyl group, and among these, the methyl group, the ethyl group, the propyl group, the butyl group, or the pentyl group is preferable.

As the alkynyl group, an alkynyl group having 2 to 6 carbon atoms is preferable. Specific examples thereof include an ethynyl group, a propynyl group, a butynyl group, a pentynyl group, and a hexynyl group, and among these, the ethynyl group, the propynyl group, the butynyl group, or the pentynyl group is preferable.

Specific examples of the cycloalkyl group include a cyclohexyl group and a cyclopentyl group, and among these, the cyclohexyl group is preferable.

Specific examples of the aryl group include a phenyl group and a naphthyl group, and among these, the phenyl group is preferable.

The group represented by R¹ may be further substituted with another substituent. As such another substituent, a hydrophilic group is preferable, and a phosphoric acid group, a hydroxy group, or a thiol group is preferable.

Furthermore, the methylene group in the group represented by R¹ may be substituted with a divalent linking group including a heteroatom. As the divalent linking group including a heteroatom, —O— or —CO— is preferable.

In a case where n1 is 2 to 4, in General Formula (I), R¹ represents an n-valent linking group.

As the divalent linking group represented by R¹, an alkylene group, a phenylene group, or a group formed by a combination thereof is preferable. The alkylene group may be linear or branched, and a hydrogen atom of the alkylene group may be substituted with such another substituent. The alkylene group preferably has 1 to 3 carbon atoms.

As the trivalent linking group represented by R¹, a group formed by removing one hydrogen atom from an alkylene group or a group formed by removing one hydrogen atom from a phenylene group is preferable. The alkylene group may be linear or branched, and a hydrogen atom of the alkylene group may be substituted with such another substituent. The alkylene group preferably has 1 to 3 carbon atoms.

As the tetravalent linking group represented by R¹, a group formed by removing two hydrogen atoms from an alkylene group or a group formed by removing two hydrogen atoms from a phenylene group is preferable. The alkylene group may be linear or branched, and a hydrogen atom of the alkylene group may be substituted with such another substituent. The alkylene group preferably has 1 to 3 carbon atoms.

Examples of the compound represented by General Formula (I) (phosphonic acid A) include methylphosphonic acid, butylphosphonic acid, phenylphosphonic acid, benzylphosphonic acid, 1,2-ethylenephosphonic acid, 1-hydroxyethane-1,1-diphosphonic acid (ethylenediaminetetramethylenephosphonic acid, also referred to as HEDP), and 1,4-phenylenediphosphonic acid, and HEDP is preferable.

A content of the phosphonic acid A is preferably 0.01% to 2.0% by mass, and more preferably 0.01% to 1.0% by mass with respect to the total mass of the cleaning composition.

A molecular weight of the organic acid included in the cleaning composition of the embodiment of the present invention is preferably 5,000 or less.

In a case where the organic acid is a high-molecular-weight compound (for example, a high-molecular-weight organic acid), the weight-average molecular weight means a weight-average molecular weight in terms of polyethylene glycol, which is measured by gel permeation chromatography (GPC).

In a case where the organic acid is a low-molecular-weight compound, it means a molecular weight thereof.

A total content of the organic acids of the embodiment of the present invention is preferably 0.01% to 25.0% by mass, more preferably 0.1% to 15.0% by mass, and still more preferably 0.3% to 5.0% by mass with respect to the total mass of the cleaning composition.

### [Organic Amine Compound]

The cleaning composition of the embodiment of the present invention includes organic amine compounds having at least one group selected from the group consisting of a primary amino group, a secondary amino group, and a tertiary amino group. Furthermore, the cleaning composition includes two or more kinds of the organic amine compounds.

Among those, the cleaning composition preferably includes at least one of an amino alcohol or an amino acid, which will be described in the latter part, and more preferably includes the amino alcohol and the amino acid.

Hereinafter, the amino alcohol and the amino acid will be described.

Furthermore, at least one group selected from the group consisting of a primary amino group, a secondary amino group, and a tertiary amino group will hereinafter also be simply referred to as an “amino group”.

In the present specification, the primary amino group refers to a group represented by —NH₂, the secondary amino group refers to a group represented by —NHR^{T}, and the tertiary amino group refers to a group represented by —N(R^{T})₂. R^{T}'s each independently represent an alkyl group which may have a substituent. R^{T} in the secondary amino group may be bonded to a structure bonded to a bonding site of the secondary amino group to form a ring. In addition, two R^{T}'s in the tertiary amino group may be bonded to each other to form a ring. It should be noted that in R^{T}, an atom directly bonded to the carbon atom having a bonding site with the nitrogen atom is a carbon atom or a hydrogen atom.

In addition, in the present specification, an atom bonded to the amino group of an organic amine compound is a carbon atom, and an atom directly bonded to the carbon atom is a carbon atom or a hydrogen atom.

### (Amino Alcohol)

The amino alcohol refers to an organic compound having an amino group and a hydroxy group in the molecule.

It is considered that by configuring the cleaning composition to include the amino alcohol, the surface roughness can be further suppressed.

The amino alcohol is preferably an organic compound having an alkane skeleton.

Furthermore, in a case where the amino alcohol also corresponds to an amino acid, it is included in the amino acid but not included in the amino alcohol.

As the amino alcohol, a compound represented by Formula (A1) or Formula (A2) is preferable.

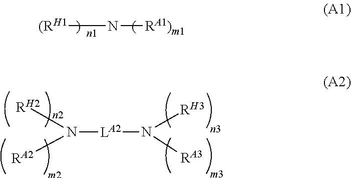

In Formula (A1), R^{A1}'s each independently represent a hydrogen atom or an alkyl group. The alkyl group represented by R^{A1} preferably has 1 to 3 carbon atoms, and more preferably has 1 or 2 carbon atoms.

In Formula (A1), R^{H1}'s each independently represent an alkyl group having at least one or more hydroxy groups. The alkyl group having at least one or more hydroxy groups, represented by R^{H1}, preferably has 1 to 6 carbon atoms, and more preferably has 2 to 4 carbon atoms. The alkyl group having at least one or more hydroxy groups, represented by R^{H1}, preferably has 1 to 6 hydroxy groups, and more preferably has 1 to 3 hydroxy groups. Examples of the group represented by R^{H1} include a hydroxymethyl group, a 1-hydroxyethyl group, a 2-hydroxyethyl group, a 3-hydroxypropyl group, a 2,3-dihydroxypropyl group, a bis(hydroxymethyl)methyl group, a tris(hydroxymethyl)methyl group, and a 2,3,4,5,6-pentahydroxyhexyl group.

In Formula (A1), n1 represents an integer of 1 to 3, and m1 represents an integer of 0 to 2. It should be noted that n1 and m1 are selected such that a sum of n1 and m1 is 3. n1 is preferably 1 or 2. m1 is preferably 1 or 2.

Examples of the compound represented by Formula (A1) include monoethanolamine, diethanolamine, triethanolamine, N-methyldiethanolamine, N-ethyldiethanolamine, trishydroxymethylaminomethane (also referred to as Tris), bis(2-hydroxyethyl)aminotrist(hydroxymethyl)methane (also referred to as Bis-Tris), glucamine, and N-methylglucamine.

In Formula (A2), R^{A2} and R⁴³ each independently represent a hydrogen atom or an alkyl group. Since preferred aspects of the groups represented by R^{A2} and R^{A3} are the same as the preferred aspects of the group represented by R^{A1}, a description thereof will not be repeated.

In Formula (A2), R^{H2} and R^{H3} each independently represent an alkyl group having at least one or more hydroxy groups. Since the preferred aspects of the groups represented by R^{H2} and R^{H3} are the same as the preferred aspects of the group represented by R^{H1}, a description thereof will not be repeated.

In Formula (A2), n2 represents an integer of 1 or 2, and m2 represents an integer of 0 or 1. It should be noted that n2 and m2 are selected such that a sum of n2 and m2 is 2.

In Formula (A2), n3 represents an integer of 1 or 2, and m3 represents an integer of 0 or 1. It should be noted that n3 and m3 are selected such that a sum of n3 and m3 is 2.

In Formula (A2), L^{A2} represents a divalent linking group. L^{A2} preferably represents an alkylene group having 1 to 6 carbon atoms.

Examples of the compound represented by Formula (A2) include 1,3-bis[tris(hydroxymethyl)methylamino]propane (also referred to as bis-trispropane).

As the amino alcohol, from the viewpoint that the surface roughness can be further suppressed, trishydroxymethylaminomethane, bis(2-1,3-hydroxyethyl)aminotrist(hydroxymethyl)methane, or bis[tris(hydroxymethyl)methylamino]propane is preferable.

A content of the amino alcohol is preferably 0.005% to 20.0% by mass, more preferably 0.01% to 15.0% by mass, and still more preferably 0.3% to 5.0% by mass with respect to the total mass of the cleaning composition.

The amino alcohols may be used alone or in combination of two or more kinds thereof. In a case where two or more kinds of the amino alcohols are used, it is also preferable that a total content thereof is in the preferred ranges.

In a case where the cleaning composition of the embodiment of the present invention includes the organic acid X and the amino alcohol, a mass ratio of the content of the organic acid X to the content of the amino alcohol is preferably 0.05 to 100, and more preferably 0.1 to 80. It is considered that by setting the mass ratio to be in the preferred ranges, the surface roughness can be further suppressed and the removability of residues is more excellent.

### (Amino Acid)

The amino acid refers to an organic compound having an amino group and a carboxy group in the molecule.

It is considered that by configuring the cleaning composition to include the amino acid, the surface roughness can be further suppressed.

Examples of the amino acid include an α-amino acid having an amino group at a carbon atom (α-carbon) to which a carboxy group is bonded, a β-amino acid having an amino group at a carbon atom (β-carbon) which is bonded to α-carbon, and a γ-amino acid having an amino group at a carbon atom (γ-carbon) which is bonded to α-carbon.

Among these, the α-amino acid is preferable from the viewpoint that the surface roughness can be further suppressed.

As the amino acid, a compound represented by Formula (B1) or Formula (B2) is preferable.

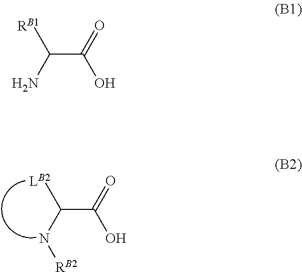

In Formula (B1), R^{B1} represents a hydrogen atom, or an alkyl group which may have a substituent. The alkyl group moiety of the alkyl group which may have a substituent, represented by RBI, preferably has 1 to 6 carbon atoms. A methylene group constituting the alkyl group moiety may be substituted with —CO—, —O—, or —S—. The alkyl group moiety may be linear or branched, and may have a cyclic structure. Examples of the substituent of the alkyl group which may have a substituent, represented by R^{B1}, include a phenyl group, a hydroxy group, a hydroxyphenyl group, a thiol group, a primary amino group, a secondary amino group, an imidazolyl group, an indolyl group, and a guanidino group, and the primary amino group, the secondary amino group, the imidazolyl group, the indolyl group, or the guanidino group is preferable. Furthermore, the alkyl group which may have a substituent, represented by R^{B1}, may have a plurality of substituents.

Examples of the compound represented by Formula (B1) include alanine, arginine, asparagine, cysteine, glutamine, glycine, histidine, leucine, isoleucine, lysine, hydroxylysine, methionine, phenylalanine, serine, threonine, tryptophan, tyrosine, and valine.

In Formula (B2), L^{B2} represents a divalent linking group. L^{B2} preferably represents an alkylene group which may have a substituent having 1 to 6 carbon atoms. Examples of the substituent include the substituents which may be contained in R^{B1}.

In Formula (B2), R^{B2} represents a hydrogen atom, or an alkyl group which may have a substituent. Since the preferred aspect of the alkyl group which may have a substituent, represented by R^{B2}, is the same as the preferred aspect of the alkyl group which may have a substituent, represented by R^{B1}, a description thereof will not be repeated.

Furthermore, in the compound represented by Formula (B2), L^{B2} is bonded to a nitrogen atom.

Examples of the compound represented by Formula (B2) include piperidine-2-carboxylic acid, N-methylpiperidine-2-carboxylic acid, proline, N-methylproline, and hydroxyproline.

As the amino acid, arginine, asparagine, glutamine, histidine, lysine, hydroxylysine, or tryptophan is preferable, and arginine, histidine, or lysine is more preferable from the viewpoint that the surface roughness can be further suppressed. That is, the basic amino acid is more preferable.

A content of the amino acid is preferably 0.005% to 10.0% by mass, more preferably 0.01% to 5.0% by mass, and still more preferably 0.03% to 0.3% by mass with respect to the total mass of the cleaning composition.

The amino acids may be used alone or in combination of two or more kinds thereof. In a case where two or more kinds of the amino acids are used, it is also preferable that a total content thereof is in the preferred ranges.

In a case where the cleaning composition of the embodiment of the present invention includes an amino acid, a mass ratio of the content of the organic acid to the content of the amino acid is preferably 0.1 to 300.0, more preferably 0.3 to 260.0, still more preferably 0.5 to 210.0, particularly preferably 2.0 to 210.0, and most preferably 2.0 to 55.0. It is considered that by setting the mass ratio to be in the preferred ranges, the surface roughness can be further suppressed and the removability of residues is more excellent.

### [Other Amine Compounds]

The organic amine compound may include other organic amine compounds different from the amino alcohol and the amino acid.

Examples of such other organic amine compounds include other organic amine compounds having an antibacterial action. Hereinafter, the organic amine compound having an antibacterial action will also be referred to as an antibacterial organic amine compound A.

Examples of such other amine compounds also include an aliphatic hydrocarbon amine compound consisting of an amino group and an aliphatic hydrocarbon group.

Examples of the aliphatic hydrocarbon amine compound include a primary alkylamine compound (for example, having 1 to 6 carbon atoms), a secondary alkylamine compound (for example, having 2 to 8 carbon atoms), and a tertiary alkylamine compound (for example, having 3 to 12 carbon atoms). The aliphatic hydrocarbon amine compound may be a diamine compound having two amino groups in the molecule or a triamine compound having three amino groups in the molecule. In addition, the aliphatic hydrocarbon groups contained in the aliphatic hydrocarbon amine compound may be bonded to each other to form a ring.

In the composition of the embodiment of the present invention, a mass ratio of the total content of the organic acids to the total content of the organic amine compounds is preferably 0.05 to 10.00, more preferably 0.10 to 6.20, and still more preferably 0.30 to 3.00. It is considered that by setting the mass ratio to be in the preferred ranges, the surface roughness can be further suppressed and the removability of residues is more excellent.

### [Antimicrobial Agent]

The cleaning composition of the embodiment of the present invention may include an antibacterial agent.

The antibacterial agent refers to a compound that can suppress the growth of bacteria, which is different from the organic acid and the organic amine compound.

Examples of the antibacterial agent include a quaternary ammonium-based antibacterial agent, a biguanide-based antibacterial agent, a sulfamide-based antibacterial agent, a peroxide-based antibacterial agent, an isothiazolone-based antibacterial agent, an imidazole-based antibacterial agent, an ester-based antibacterial agent, an alcohol-based antibacterial agent, a carbamate-based antibacterial agent, an iodine-based antibacterial agent, and an antibiotic substance.

Examples of the quaternary ammonium-based antibacterial agent include benzalkonium chloride, didecyldimethylammonium chloride (DDAC), hexadecylpyridinium chloride (CPC), 3,3′-(2,7-dioxaoctane)bis(1-dodecylpyridinium bromide) (Hyjeria), benzethonium chloride, and domiphen bromide. Among these, benzethonium chloride is preferable.

Examples of the biguanide-based antibacterial agent include bis(p-chlorophenyldiguanide)hexanedigluconate (chlorhexidine gluconate) and poly(hexamethylene biguanide) hydrochloride (hexamethylene biguanidine hydrochloride). Among these, chlorhexidine gluconate is preferable.

Examples of the sulfamide-based antibacterial agent include N-dichlorofluoromethylthio-N′,N′-dimethyl-N-phenylsulfamide (dichlorfluoramide) and N-dichlorofluoromethylthio-N′,N′-dimethyl-N-p-tolylsulfamide (tolylfluanide). Among these, tolylfluanide is preferable.

Examples of the isothiazolinone-based antibacterial agent include 2-methyl-4-isothiazolin-3-one (MIT), 2-octyl-4-isothiazolin-3-one (OIT), 1,2-benzisothiazol-3 (2H)-one (BIT), and 5-chloro-2-methyl-4-isothiazolin-3-one (CIT). Among these, MIT, OIT, or BIT is preferable, and MIT or OIT is more preferable.

Examples of the imidazole-based antibacterial agent include 2-(4-thiazolyl)-benzimidazole (TBZ) and methyl 2-benzimidazolecarbamate (PREVENTOL BCM).

Examples of the ester-based antibacterial agent include glycerol laurate (monoglyceride).

Examples of the alcohol-based antimicrobial agent include phenoxyethanol, 1,2-pentanediol, and 1,2-hexanediol.

Examples of the carbamate-based antibacterial agent include 3-iodo-2-propynylbutyl carbamate (Glycacil).

Examples of the iodine-based antibacterial agent include [(4-chlorophenoxy)methyl]-3-iodo-2-propynyl ether (IF1000).

In a case where the cleaning composition of the embodiment of the present invention includes the antibacterial agent, a mass ratio of the total content of the organic amine compounds to the content of the antibacterial agent is preferably 0.1 to 200, more preferably 3 to 150, and still more preferably 5 to 100. It is considered that by setting the mass ratio to be in the preferred ranges, the surface roughness can be further suppressed and the removability of residues is more excellent.

In a case where the cleaning composition of the embodiment of the present invention includes the antibacterial agent and the amino acid, a mass ratio of the content of the amino acid to the content of the antibacterial agent is preferably 0.1 to 200, more preferably 0.4 to 100, and still more preferably 0.5 to 10. It is considered that by setting the mass ratio to be in the preferred ranges, the surface roughness can be further suppressed and the removability of residues is more excellent.

The cleaning composition of the embodiment of the present invention also preferably includes one or more kinds of antibacterial compounds selected from the group consisting of the organic acid XA, the antibacterial aromatic organic acid A, the antibacterial organic acid A, the antibacterial organic amine compound A, and the antibacterial agent.

A total content of the antibacterial compounds is preferably 0.001% to 2.0% by mass, and more preferably 0.01% to 1.0% by mass with respect to the total mass of the cleaning composition.

In addition, in a case where the cleaning composition of the embodiment of the present invention includes the antibacterial compound and the amino acid, a mass ratio AX of the content of the amino acid to the content of the antibacterial compound is preferably 0.1 to 200, more preferably 0.4 to 100, and still more preferably 0.5 to 10.

In a case where the cleaning composition of the embodiment of the present invention includes the antibacterial compound, a mass ratio AY of the total content of the organic amine compounds to the content of the antibacterial compound is preferably 0.1 to 200, more preferably 3 to 150, and still more preferably 5 to 100.

It should be noted that in a case where the organic amine compounds and the compound corresponding to the antibacterial organic amine compound A are included in the calculation of the mass ratio AY, the content of the compound is calculated as the content of the antibacterial organic amine compound A, and is not included in the content of the organic amine compounds.

### [Solvent]

The cleaning composition of the embodiment of the present invention preferably includes a solvent.

Examples of the solvent include water and an organic solvent.

It is preferable that the organic solvent is mixed with water at an optional ratio.

Examples of the organic solvent include an alcohol-based solvent, a glycol-based solvent, a glycol ether-based solvent, a ketone-based solvent, and a sulfur-containing solvent.

Examples of the alcohol-based solvent include methanol, ethanol, propanol, isopropyl alcohol, 1-butanol, 2-butanol, isobutyl alcohol, and tert-butyl alcohol.

Examples of the glycol-based solvent include ethylene glycol, propylene glycol, diethylene glycol, dipropylene glycol, triethylene glycol, and tetraethylene glycol. Examples of the glycol ether-based solvent include glycol monoether.

Examples of the glycol monoether include ethylene glycol monomethyl ether, ethylene glycol monoethyl ether, ethylene glycol mono n-propyl ether, ethylene glycol monoisopropyl ether, ethylene glycol mono n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

Examples of the ketone-based solvent include acetone, methyl ethyl ketone, methyl isobutyl ketone, and cyclohexanone.

Examples of the sulfur-containing solvent include dimethyl sulfone, dimethyl sulfoxide, and sulfolane.

Water is preferable as the solvent. As the water, distilled water, deionized water, pure water, or ultrapure water is preferable, and pure water or ultrapure water is more preferable.

A content of the solvent is preferably 70% to 99% by mass, more preferably 80% to 98% by mass, and still more preferably 90% to 97% by mass with respect to the total mass of the cleaning composition.

The solvents may be used alone or in combination of two or more kinds thereof. In a case where two or more kinds of the solvents are used, it is also preferable that a total content thereof is in the preferred ranges.

### [pH Adjuster]

The cleaning composition of the embodiment of the present invention may include a pH adjuster. A pH of the cleaning composition may be adjusted to a preferred pH range which will be described later by the pH adjuster.

The pH adjuster is preferably a compound different from the compound. Examples of the pH adjuster include an acidic compound and a basic compound.

The acidic compound is an acidic compound that exhibits acidity (a pH of less than 7.0) in an aqueous solution.

Examples of the acidic compound include an inorganic acid and a salt thereof.

Examples of the inorganic acid include sulfuric acid, hydrochloric acid, nitric acid, phosphoric acid, and salts thereof.

A content of the acidic compound is preferably 0.1% to 10.0% by mass, and more preferably 0.3% to 5.0% by mass with respect to the total mass of the cleaning composition.

The basic compound is a compound that exhibits alkalinity (a pH of more than 7.0) in an aqueous solution.

Examples of the basic compound include an inorganic base, an organic base, and salts thereof.

Examples of the inorganic base include alkali metal hydroxides such as sodium hydroxide and potassium hydroxide, alkaline earth metal hydroxides, and ammonia.

Examples of the organic base include a quaternary ammonium salt. The anion contained in the quaternary ammonium salt is preferably Cl⁻, Br⁻, or OH⁻, more preferably Cl⁻ or OH⁻, and still more preferably OH⁻.

A content of the basic compound is preferably 0.1% to 10.0% by mass, and more preferably 0.3% to 5.0% by mass with respect to the total mass of the cleaning composition.

### [Other Components]

The cleaning composition of the embodiment of the present invention may include other components, in addition to the components.

Hereinafter, such other components will be described.

### (Polyhydroxy Compound Having Molecular Weight of 500 or More)

The cleaning composition may include a polyhydroxy compound having a molecular weight of 500 or more.

The polyhydroxy compound is a compound different from the compound that can be included in the cleaning composition.

The polyhydroxy compound is an organic compound having 2 or more (for example, 2 to 200) alcoholic hydroxyl groups in one molecule.

A molecular weight (a weight-average molecular weight in a case of having a molecular weight distribution) of the polyhydroxy compound is 500 or more, preferably 500 to 100,000, and more preferably 500 to 3,000.

Examples of the polyhydroxy compound include polyoxyalkylene glycols such as polyethylene glycol, polypropylene glycol, and polyoxyethylene polyoxypropylene glycol; oligosaccharides such as manninotriose, cellotriose, gentianose, raffinose, melezitose, cellotetrose, and stachyose; and polysaccharides such as starch, glycogen, cellulose, chitin, and chitosan, and hydrolysates thereof.

Cyclodextrin is also preferable as the polyhydroxy compound.

The cyclodextrin means one kind of cyclic oligosaccharide having a cyclic structure in which a plurality of D-glucoses are bonded by a glucoside bond. A compound in which 5 or more (for example, 6 to 8) glucoses are bonded is known.

Examples of the cyclodextrin include α-cyclodextrin, β-cyclodextrin, and γ-cyclodextrin, and the γ-cyclodextrin is preferable.

The polyhydroxy compounds may be used alone or in combination of two or more kinds thereof.

A content of the polyhydroxy compound is preferably 0.01% to 10% by mass, more preferably 0.05% to 5% by mass, and still more preferably 0.1% to 3% by mass with respect to the total mass of the cleaning composition.

The content of the polyhydroxy compound is preferably 0.01% to 30% by mass, more preferably 0.05% to 25% by mass, and still more preferably 0.5% to 20% by mass with respect to a total mass of the components of the cleaning composition excluding the solvent.

### (Reducing Sulfur Compound)

The cleaning composition may include a reducing sulfur compound.

The reducing sulfur compound is a compound different from the compound that can be included in the cleaning composition.

The reducing sulfur compound is a compound that has reducing properties and includes a sulfur atom.

The reducing sulfur compound can improve a corrosion preventing action of the cleaning composition. That is, the reducing sulfur compound can act as an anticorrosive agent.

Examples of the reducing sulfur compound include mercaptosuccinic acid, dithiodiglycerol, bis(2,3-dihydroxypropylthio)ethylene, sodium 3-(2,3-dihydroxypropylthio)-2-methyl-propylsulfonate, 1-thioglycerol, sodium 3-mercapto-1-propanesulfonate, 2-mercaptoethanol, thioglycolic acid, and 3-mercapto-1-propanol.

Among those, a compound having an SH group (mercapto compound) is preferable, and 1-thioglycerol, sodium 3-mercapto-1-propanesulfonate, 2-mercaptoethanol, 3-mercapto-1-propanol, or thioglycolic acid is more preferable.

The reducing sulfur compound may be used alone or in combination of two or more kinds thereof.

A content of the reducing sulfur compound is preferably 0.01% to 10% by mass, more preferably 0.05% to 5% by mass, and still more preferably 0.1% to 3% by mass with respect to the total mass of the cleaning composition.

A content of the reducing sulfur compound is preferably 0.01% to 30.0% by mass, more preferably 0.05% to 25.0% by mass, and still more preferably 0.5% to 20.0% by mass with respect to the total mass of the components in the cleaning composition excluding the solvent.

### (Oxidizing Agent)

It is preferable that the cleaning composition of the embodiment of the present invention substantially does not include an oxidizing agent. The expression that the oxidizing agent is substantially not included means that a content of the oxidizing agent is 0.1% by mass or less with respect to the total mass of the cleaning composition, and the content is more preferably 0.01% by mass or less, and still more preferably 0.005% by mass or less. A lower limit thereof is, for example, 0% by mass.

Examples of the oxidizing agent include perchloric acid or a salt thereof, periodic acid or a salt thereof, persulfuric acid or a salt thereof, permanganate, iron chloride, chlorate, hypochlorite, hydrogen peroxide, peracetic acid, perbenzoic acid, metachloroperbenzoic acid, isocyanuric acid, isocyanurate, trichloroisocyanuric acid, and trichloroisocyanurate.

### (Surfactant)

It is preferable that the cleaning composition of the embodiment of the present invention substantially does not include a surfactant.

The expression that the surfactant is substantially not included means that a content of the surfactant is 0.05% by mass or less with respect to the total mass of the cleaning composition, and the content is preferably 0.01% by mass or less, and more preferably 0.0001% by mass or less. A lower limit thereof is, for example, 0% by mass.

Examples of the surfactant include a compound having a hydrophilic group and a hydrophobic group (lipophilic group) in one molecule, and examples thereof include an anionic surfactant, a cationic surfactant, and a nonionic surfactant.

Furthermore, in the cleaning composition, each of the components described in the present specification may form a salt with another component.

### <Properties of Cleaning Composition>

Preferred properties of the cleaning composition of the embodiment of the present invention will be described.

[pH]

A pH of the cleaning composition of the embodiment of the present invention is preferably 1 to 12, more preferably 2 to 9, and still more preferably 3 to 8.

It is considered that by setting the pH of the cleaning composition to be in the preferred ranges, the surface roughness can be further suppressed and the removability of residues is more excellent.

The pH of the cleaning composition can be measured by a method based on JIS Z8802-1984, using a known pH meter. The measurement temperature is set to 25° C.

### [Surface Tension]

A surface tension of the cleaning composition of the embodiment of the present invention is preferably 65 to 75 mN/m.

The surface tension of the cleaning composition is referred to a value measured by a lamellar length measurement method, and can be measured using “DY-700” manufactured by Kyowa Interface Science Co., Ltd.

### [Insoluble Particles]

It is preferable that the cleaning composition of the embodiment of the present invention substantially does not include insoluble particles.

The “insoluble particles” are particles of an inorganic solid, an organic solid, and the like, and correspond to particles which are present as particles without being finally dissolved in the cleaning composition.

The expression that “the insoluble particles are substantially not included” means that the number of particles having a particle diameter of 50 nm or more included in 1 mL of a composition for measurement is 40,000 or less in a case where the cleaning composition is diluted 10,000 times with the solvent included in the cleaning composition to obtain the composition for measurement. Furthermore, the number of the particles included in the composition for measurement can be measured in a liquid phase using a commercially available particle counter.

As a commercially available particle counter device, a device manufactured by RION Co., Ltd. or PMS Co., Ltd. can be used. Representative examples of the device of the former include KS-19F, and representative examples of the device of the latter include Chem20. In order to measure larger coarse particles, a device such as KS-42 series or LiQuilaz II S series can be used.

Examples of the insoluble particles include inorganic solids such as silica (including colloidal silica and fumed silica), alumina, zirconia, ceria, titania, germania, manganese oxide, and silicon carbide; and organic solids such as polystyrene, a polyacrylic resin, and polyvinyl chloride.

Examples of a method for removing the insoluble particles from the cleaning composition include a purification treatment such as filtering.

### (Coarse Particles)

The cleaning composition of the embodiment of the present invention may include coarse particles, but a content thereof is preferably low.

The coarse particles mean particles having a diameter (particle diameter) of 1 μm or more in a case where the shape of the particles is regarded as a sphere. Furthermore, the particles included in the insoluble particles may be included in the coarse particles.

As a content of the coarse particles in the cleaning composition, the content of the particles having a particle diameter of 1 μm or more is preferably 100 particles or less, and more preferably 50 particles or less per milliliter of the cleaning composition. A lower limit thereof is preferably 0 or more, and more preferably 0.01 or more per milliliter of the cleaning composition.

The coarse particles included in the cleaning composition correspond to particles of dust, dirt, organic solids, inorganic solids, or the like included as impurities in raw materials, and particles of dust, dirt, organic solids, inorganic solids, or the like brought in as contaminants during the preparation of the cleaning composition, which are present as particles without being finally dissolved in the cleaning composition.

The number of the coarse particles present in the cleaning composition can be measured in a liquid phase, using a commercially available particle counter.

Examples of a method for removing the coarse particles include a purification treatment such as filtering which will be described later.

### <Method for Producing Cleaning Composition>

The cleaning composition can be produced by a known method. Hereinafter, a method for producing the cleaning composition will be described in detail.

### [Liquid Preparing Step]

The method for preparing the cleaning composition includes, for example, mixing each of components to produce the cleaning composition.

The order and/or the timing of mixing each of the components is not particularly limited, and for example, an organic acid and two or more kinds of organic amine compounds are sequentially added to a container into which a purified solvent (for example, pure water) has been put, and then the mixture is stirred to be mixed. Furthermore, after the mixing, a pH adjuster may be added to adjust the pH of the mixed solution. In addition, in a case where the solvent and each of the components are added to the container, the components may be added all at once or dividedly a plurality of times.

As a stirring device and a stirring method used for preparing the cleaning composition, a known device may be used as a stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and bead mills.

The mixing of each of the components in the liquid preparing step of the cleaning composition, a purification treatment which will be described later, and the storage of the produced cleaning composition are preferably performed at 40° C. or lower, and more preferably performed at 30° C. or lower. In addition, a lower limit thereof is preferably 5° C. or higher, and more preferably 10° C. or higher. By performing the liquid preparation, the treatment, and/or the storage of the cleaning composition in the temperature ranges, the performance can be stably maintained for a long period of time.

### (Purification Treatment)

It is preferable that any one or more of the raw materials for producing the cleaning composition are subjected to a purification treatment in advance. Examples of the purification treatment include known methods such as distillation, ion exchange, and filtration (filtering).

With regard to the degree of purification, it is preferable to perform the purification until the purity of the raw material is 99% by mass or more, and it is more preferable to perform the purification until the purity of the stock solution is 99.9% by mass or more.

Examples of the method for the purification treatment include a method in which raw materials are passed through an ion exchange resin, a reverse osmosis membrane (RO membrane), or the like, distillation of a raw materials, and filtering which will be described later.

As the purification treatment, a plurality of the purification methods may be combined and carried out. For example, the raw materials are subjected to primary purification by passing through an RO membrane, and then subjected to secondary purification by passing through a purification device consisting of a cation exchange resin, an anion exchange resin, or a mixed bed type ion exchange resin.

In addition, the purification treatment may be carried out a plurality of times.

### (Filtering)

A filter that is used for the filtering is not particularly limited as long as it is a filter which has been used in filtration applications and the like since the related art. Examples thereof include filters formed of fluororesins such as polytetrafluoroethylene (PTFE) and tetrafluoroethylene perfluoroalkyl vinyl ether copolymer (PFA), polyamide-based resins such as nylon, and polyolefin resins (including those with a high density and an ultra-high molecular weight) such as polyethylene and polypropylene (PP). Among these materials, a material selected from the group consisting of the polyethylene, the polypropylene (including a high-density polypropylene), the fluororesin (including PTFE and PFA), and the polyamide-based resin (including nylon) is preferable, and the filter with the fluororesin is more preferable. In a case of performing the filtration of the raw materials using a filter formed with these materials, high-polarity foreign matters which are likely to cause defects can be effectively removed.

A critical surface tension of the filter is preferably 70 to 95 mN/m, and more preferably 75 to 85 mN/m. Furthermore, the value of the critical surface tension of the filter is a nominal value of a manufacturer. By using a filter having a critical surface tension in the ranges, high-polarity foreign matters which are likely to cause defects can be effectively removed.

A pore diameter of the filter is preferably 2 to 20 nm, and more preferably 2 to 15 nm. By setting the pore diameter of the filter to be in the ranges, it is possible to reliably remove fine foreign matters such as impurities and aggregates included in the raw materials while suppressing clogging in filtering. With regard to the pore diameters herein, reference can be made to nominal values of filter manufacturers.

The filtering may be performed only once or twice or more. In a case where the filtering is performed twice or more, the filters used may be the same as or different from each other.

Furthermore, the filtering is preferably performed at room temperature (25° C.) or lower, more preferably performed at 23° C. or lower, and still more preferably performed at 20° C. or lower. In addition, the temperature is preferably 0° C. or higher, more preferably 5° C. or higher, and still more preferably 10° C. or higher. By performing the filtering in the temperature ranges, the amount of particulate foreign matter and impurities dissolved in the raw material can be reduced, and the foreign matter and the impurities can be efficiently removed.

### (Container)

The cleaning composition (including an aspect of a diluted cleaning composition which will be described later) can be packed in any container, stored, transported, and used as long as corrosiveness or the like is not problematic.

In semiconductor applications, as the container, a container that has a high degree of cleanliness inside the container and suppressed elution of impurities from an inner wall of an accommodating portion of the container into each liquid is preferable. Examples of such a container include various containers commercially available as a container for a semiconductor cleaning composition, such as “CLEAN BOTTLE” series manufactured by AICELLO MILIM CHEMICAL Co., Ltd. and “PURE BOTTLE” manufactured by Kodama Plastics Co., Ltd., but the container is not limited to these.

In addition, as the container for accommodating the cleaning composition, a container in which a liquid contact portion with each liquid, such as an inner wall of the accommodating portion, is formed from a fluororesin (perfluororesin) or a metal which has been subjected to rust prevention and metal elution prevention treatments is preferable.

It is preferable that the inner wall of the container is formed of one or more resins selected from the group consisting of a polyethylene resin, a polypropylene resin, and a polyethylene-polypropylene resin, or a resin different from the resins, or a metal which has been subjected to rust prevention and metal elution prevention treatments, such as stainless steel, Hastelloy, Inconel, and Monel.

The different resin is preferably the fluororesin (perfluororesin). In this manner, by using a container having an inner wall formed of a fluororesin, the occurrence of a problem of elution of ethylene or propylene oligomers can be suppressed, as compared with a container having an inner wall formed of a polyethylene resin, a polypropylene resin, or a polyethylene-polypropylene resin.

Examples of such a container having an inner wall which is a fluororesin include a FluoroPure PFA composite drum manufactured by Entegris Inc. In addition, the containers described on page 4 of JP1991-502677A (JP-H03-502677A), page 3 of WO2004/016526A, and on pages 9 and 16 of WO99/46309A can also be used.

In addition, for the inner wall of the container, quartz and an electropolished metal material (that is, a completely electropolished metal material) are also preferably used, in addition to the fluororesin.

The metal material used for producing the electropolished metal material is preferably a metal material which includes at least one selected from the group consisting of chromium and nickel, and has a total content of chromium and nickel of more than 25% by mass with respect to a total mass of the metal material, and examples thereof include stainless steel and a nickel-chromium alloy.

The total content of chromium and nickel in the metal material is more preferably 30% by mass or more with respect to a total mass of the metal material.

Furthermore, an upper limit of the total content of Cr and Ni in the metal material is generally preferably 90% by mass or less.

As a method for electropolishing the metal material, the known method can be used. For example, the methods described in paragraphs [0011] to [0014] of JP2015-227501A, paragraphs [0036] to [0042] of JP2008-264929A, or the like can be used.

The inside of these containers is preferably cleaned before filling the cleaning composition. With regard to a liquid used for the cleaning, the amount of metal impurities in the liquid is preferably reduced. The cleaning composition may be bottled in a container such as a gallon bottle and a coated bottle after the production, and then may be transported and stored.

In order to prevent changes in the components of the cleaning composition during the storage, the inside of the container may be purged with an inert gas (nitrogen, argon, and the like) having a purity of 99.99995% by volume or more. Particularly, a gas with a low moisture content is preferable. In addition, during the transportation and the storage, the temperature may be normal temperature or may be controlled in a range of −20° C. to 20° C. to prevent deterioration.

### (Clean Room)

It is preferable that the handling including the production of the cleaning composition, the opening and the cleaning of the container, the filling of the cleaning composition, and the like, a treatment analysis, and a measurement are all performed in a clean room. It is preferable that the clean room satisfies 14644-1 clean room standards. The clean room preferably satisfies any of International Organization for Standardization (ISO) class 1, ISO class 2, ISO class 3, or ISO class 4, more preferably ISO class 1 or ISO class 2, and still more preferably ISO class 1.

### [Diluting Step]

The cleaning composition may be provided to be used as a cleaning composition which has been diluted (diluted cleaning composition) after a diluting step of diluting the cleaning composition using a diluent.

Furthermore, the diluted cleaning composition is also a form of the cleaning composition of the embodiment of the present invention as long it satisfies as the requirements of the present invention.

Examples of the diluted liquid include water and an aqueous solution including ammonia.

It is preferable that the diluted liquid used in the diluting step is subjected to a purification step in advance. In addition, it is more preferable that the diluted cleaning composition obtained in the diluting step is subjected to a purification treatment.

Examples of the purification treatment include an ion component reducing treatment using an ion exchange resin, an RO membrane, or the like, and a foreign matter removing treatment using filtering, which are described as the purification treatment for the cleaning composition, and it is preferable to perform any of these treatments.

A dilution ratio of the cleaning composition in the diluting step may be appropriately adjusted depending on the kind and the content of each component, and the use target and the purpose of the cleaning composition. A ratio (dilution ratio) of the diluted cleaning composition to the cleaning composition before the dilution in terms of a mass ratio or a volume ratio (volume ratio at 23° C.) is preferably 1.5 to 10,000 times, more preferably 2 to 2,000 times, and still more preferably 50 to 1,000 times.

In addition, a cleaning composition (diluted cleaning composition) including each component in an amount obtained by dividing a suitable content of each component (excluding water) included in the cleaning composition by a dilution ratio in the ranges (for example, 100) can also be suitably put into practical use.

In other words, a suitable content of each component (excluding water) with respect to the total mass of the diluted cleaning composition is an amount obtained, for example, by dividing the amount described as the suitable content of each component with respect to the total mass of the cleaning composition (cleaning composition before the dilution) by a dilution ratio in the ranges (for example, 100).

A change in pH before and after the dilution (a difference between the pH of the cleaning composition before the dilution and the pH of the diluted cleaning composition) is preferably 2.0 or less, more preferably 1.8 or less, and still more preferably 1.5 or less.

It is preferable that the pH of the cleaning composition before the dilution and the pH of the diluted cleaning composition are each in the suitable aspect.

A specific method for the diluting step of diluting the cleaning composition may be performed according to the liquid preparing step for the cleaning composition. The stirring device and the stirring method used in the diluting step may also be performed using the known stirring device mentioned in the liquid preparing step of for the cleaning composition.

### <Use of Cleaning Composition and Method for Using Cleaning Composition>

A use of the cleaning composition, an object to be cleaned, a cleaning method, and a method for using the cleaning composition will be described in detail below.

### [Use of Cleaning Composition]

The cleaning composition is used in a treatment of an Mo-containing substrate. Above all, the cleaning composition is preferably used in the cleaning of an Mo-containing substrate, and more preferably used in a step of cleaning an Mo-containing semiconductor substrate in a process for manufacturing an Mo-containing semiconductor substrate.

Among those, the cleaning composition is preferably used in a cleaning step of cleaning an Mo-containing semiconductor substrate which has been subjected to a chemical mechanical polishing (CMP) treatment. Additionally, the cleaning composition can also be used for a buffing treatment as described later. In addition, the cleaning composition can be used in the cleaning of a device and the like used in a process for manufacturing a semiconductor substrate.

For the cleaning of the Mo-containing substrate, a diluted cleaning composition obtained by diluting the cleaning composition may be used.

Hereinafter, an object to be cleaned, in which the cleaning composition is preferably used, will be described in detail.

### [Object to Be Cleaned]

The object to be cleaned is an Mo-containing substrate including Mo.

As the Mo-containing substrate including Mo, an Mo-containing substrate having a region including Mo and an Mo-based residue including Mo is preferable, and an Mo-containing semiconductor substrate having a region including Mo and an Mo-based residue including Mo is more preferable.

The Mo-containing substrate which is the object to be cleaned is preferably manufactured by subjecting an Mo-containing substrate to a CMP treatment. That is, it is preferable that the Mo-based residue is a residue generated by subjecting an Mo-containing substrate to a CMP treatment. In addition, the Mo-containing substrate may be manufactured by performing a CMP treatment, and then performing buffing.

The Mo-containing substrate is not particularly limited as long as it includes Mo.

Examples of a form in which Mo exists include a metal, an oxide, and a nitride, and the metal is preferable. That is, the region including Mo is preferably a region including Mo in the metallic state.

In a case where the Mo-containing substrate includes Mo in the metallic state, the Mo contained therein may be in a state of an alloy including Mo. Examples of an element other than Mo included in the alloy including Mo include Cu, Co, W, Ru, Al, Ti, and Ta, and W is preferable.

Mo in the metallic state may be included as a metal wiring line film or as a barrier metal in the Mo-containing substrate.

In a case where the object to be cleaned is an Mo-containing semiconductor substrate, a wafer constituting the semiconductor substrate is not particularly limited. Examples of the wafer include a wafer consisting of a silicon-based material such as a silicon (Si) wafer, a silicon carbide (SiC) wafer and a resin-based wafer including silicon (glass epoxy wafer), a gallium phosphorus (GaP) wafer, a gallium arsenic (GaAs) wafer, and an indium phosphorus (InP) wafer.

The silicon wafer may be an n-type silicon wafer in which a silicon wafer is doped with a pentavalent atom (for example, phosphorus (P), arsenic (As), and antimony (Sb)), and a p-type silicon wafer in which a silicon wafer is doped with a trivalent atom (for example, boron (B) and gallium (Ga)). The silicon of the silicon wafer may be, for example, any one of amorphous silicon, single crystal silicon, polycrystalline silicon, and polysilicon.

In a case where the object to be cleaned is an Mo-containing semiconductor substrate, the semiconductor substrate may have an insulating film on the above-described wafer.

Specific examples of the insulating film include a silicon oxide film (for example, a silicon dioxide (SiO₂) film and a tetraethyl orthosilicate (Si(OC₂H₅)₄) film (TEOS film)), a silicon nitride film (for example, silicon nitride (Si₃N₄) and silicon nitride carbide (SiNC)), and a low-dielectric-constant (Low-k) film (for example, a carbon-containing silicon oxide (SiOC) film and a silicon carbide (SiC) film). Among these, the low-dielectric-constant (Low-k) film is preferable.

### (CMP Treatment)

As the object to be cleaned with the cleaning composition, an Mo-containing semiconductor substrate having an Mo-based residue after a CMP treatment is preferable.

The CMP treatment is a treatment in which a surface of a substrate having a metal wiring line film, a barrier metal, and an insulating film is flattened by a combined action of a chemical action using a polishing slurry including polishing fine particles (abrasive grains) and mechanical polishing. Furthermore, at least one of the metal wiring line film or the barrier metal includes Mo.

A surface of the Mo-containing semiconductor substrate which has been subjected to the CMP treatment may have impurities remaining thereon, such as abrasive grains (for example, silica and alumina) used in the CMP treatment, a polished Mo metal wiring line film, and metal impurities (Mo-based residues) derived from the barrier metal. For example, since these impurities may short-circuit the wiring lines and deteriorate the electrical characteristics of a semiconductor substrate, the semiconductor substrate which has been subjected to the CMP treatment is subjected to a cleaning treatment for removing these impurities from the surface.

Specific examples of the semiconductor substrate which has been subjected to the CMP treatment include the substrate which has been subjected to a CMP treatment, described in Vol. 84, No. 3, 2018, but the present invention is not limited thereto.

### (Buffing Treatment)

A surface of an Mo-containing substrate which is the object to be cleaned with the cleaning composition may be subjected to a buffing treatment after carrying out the CMP treatment.

The buffing treatment is a treatment for reducing impurities on the surface of the Mo-containing substrate using a polishing pad. Specifically, the surface of the Mo-containing substrate which has been subjected to the CMP treatment and the polishing pad are brought into contact with each other, and the Mo-containing substrate and the polishing pad are slid relative to each other while supplying a composition for buffing to the contact portion. As a result, impurities on the surface of the Mo-containing substrate are removed by a frictional force of the polishing pad and a chemical action of a composition for buffing.

As the composition for buffing, a known composition for buffing can be appropriately used depending on the type of the substrate, and the type and the amount of impurities to be removed. The component included in the composition for buffing is not particularly limited, and examples thereof include a water-soluble polymer such as a polyvinyl alcohol, water as a dispersion medium, and an acid such as nitric acid.

A polishing device, polishing conditions, and the like which are used in the buffing treatment can be appropriately selected from known devices and conditions according to the type of the substrate, the object to be removed, and the like. Examples of the buffing treatment

include the treatments described in paragraphs to of WO2017/169539A, the contents of which are incorporated herein by reference.

In addition, in one embodiment of the buffing treatment, it is also preferable that an Mo-containing substrate is subjected to a buffing treatment using the cleaning composition as the composition for buffing. That is, it is also preferable that the cleaning composition is used for buffing, using an Mo-containing substrate having Mo-based residues after the CMP treatment as an object to be cleaned.

### [Cleaning Method]

Hereinafter, a method for cleaning an Mo-containing substrate, using the cleaning composition, will be described. As one aspect of the cleaning method, a method for cleaning an Mo-containing substrate after a CMP treatment will be described.

The cleaning method is not limited to aspects which will be described below, and may be carried out by, for example, an appropriate method depending on the use.

The cleaning method using the cleaning composition is not particularly limited as long as it includes a cleaning step of cleaning an Mo-containing substrate which has been subjected to a CMP treatment. The method for cleaning an Mo-containing substrate preferably includes a cleaning step by applying the diluted cleaning composition obtained in the diluting step to an Mo-containing substrate which has been subjected to a CMP treatment.

The cleaning step of cleaning the Mo-containing substrate with the cleaning composition is not particularly limited as long as it is a known method for an Mo-containing substrate which has been subjected to a CMP treatment, and a method generally performed in this field, such as a scrub cleaning method in which residues and the like are removed by physically bringing a cleaning member such as a brush into contact with a surface of an Mo-containing substrate while supplying a cleaning composition to the Mo-containing substrate, an immersion method in which an Mo-containing substrate is immersed in the cleaning composition, a spinning (dropping) method in which the cleaning composition is added while rotating an Mo-containing substrate, and a spraying method in which the cleaning composition is sprayed. In the immersion-type cleaning, it is preferable that the cleaning composition in which an Mo-containing substrate is immersed is subjected to an ultrasonic treatment from the viewpoint that the impurities remaining on a surface of the Mo-containing substrate can be further reduced.

The cleaning step may be carried out only once or twice or more. In a case where the cleaning is carried out two or more times, the same method may be repeated or different methods may be combined.

As a method for cleaning the Mo-containing substrate, either a single-wafer method or a batch method may be adopted. The single-wafer method is generally a method in which Mo-containing substrates are treated one by one, and the batch method is generally a method in which a plurality of Mo-containing substrates are treated at the same time.

A temperature of the cleaning composition used in the cleaning of the Mo-containing substrate is not particularly limited as long as it is a temperature that is usually used in this field. Generally, the cleaning is performed at room temperature (about 25° C.), but any temperature can be selected in order to improve the cleaning properties and suppress the damage resistance to a member. For example, the temperature of the cleaning composition is preferably 10° C. to 60° C., and more preferably 15° C. to 50° C.

A cleaning time in the cleaning of the Mo-containing substrate is not particularly limited, but from the viewpoint of practical use, the cleaning time is preferably 10 seconds to 2 minutes, more preferably 20 seconds to 1 minute 30 seconds, and still more preferably 30 seconds to 1 minute.

A supply amount (supply rate) of the cleaning composition in the cleaning step for the Mo-containing substrate is not particularly limited, but is preferably 50 to 5,000 mL/min, and more preferably 500 to 2,000 mL/min.

In the cleaning of the Mo-containing substrate, a mechanical stirring method may be used in order to further improve the cleaning ability of the cleaning composition.

Examples of the mechanical stirring method include a method in which the cleaning composition is circulated on the Mo-containing substrate, a method in which the cleaning composition is flown or sprayed on the Mo-containing substrate, and a method in which the cleaning composition is stirred with ultrasonic waves or megasonic waves.

After the cleaning of the Mo-containing substrate, a step of rinsing and cleaning the Mo-containing substrate by rinsing with a solvent (hereinafter referred to as a “rinsing step”) may be performed.

The rinsing step is preferably a step which is performed continuously subsequently after the cleaning step for the Mo-containing substrate, and involves performing rinsing with a rinsing solvent (rinsing liquid) over 5 seconds to 5 minutes. The rinsing step may be performed using the above-mentioned mechanical stirring method.

Examples of the rinsing liquid include water (preferably deionized water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (aqueous ammonium hydroxide which has been diluted, and the like) may be used.

As a method in which the rinsing liquid is brought into contact with the Mo-containing substrate, the above-described method in which the cleaning composition is brought into contact with the Mo-containing substrate can be similarly adopted.

In addition, after the rinsing step, a drying step of drying the Mo-containing substrate may be performed.

The drying method is not particularly limited, and examples thereof include a spin drying method, a method in which a dry gas is flown through an Mo-containing substrate, a method in which a substrate is heated by a heating unit such as a hot plate or an infrared lamp, a Marangoni drying method, a Rotagoni drying method, an isopropyl alcohol (IPA) drying method, and any combination thereof.

The cleaning method for cleaning an Mo-containing substrate with the cleaning composition of the embodiment of the present invention can be suitably used in the manufacture of a semiconductor substrate. That is, the present invention also relates to a method for manufacturing a semiconductor substrate, the method including a step of cleaning an Mo-containing substrate, using the cleaning composition.

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### <Production of Cleaning Composition>

In Example 1, citric acid, trishydroxymethylaminomethane (Tris), and L-arginine were mixed with water such that contents thereof were as shown in the table shown in the latter part to obtain a mixed solution, and then the mixed solution was sufficiently stirred with a stirrer to obtain a cleaning composition of Example 1. Furthermore, the pH of the cleaning composition was adjusted to a value shown in the table shown in the latter part with sulfuric acid and an aqueous potassium hydroxide solution to obtain a mixed solution.

Cleaning compositions of each of Examples and each of Comparative Examples were produced by the same procedure as in Example 1, except that the type and the amount of each component were changed according to the table shown in the latter part.

Furthermore, in Example 2, the pH of the cleaning composition was adjusted using phosphoric acid and an aqueous potassium hydroxide solution. In Example 3, the pH of the cleaning composition was adjusted using phosphoric acid and tetraethylammonium hydroxide. In Example 4, the pH of the cleaning composition was adjusted using sulfuric acid and tetraethylammonium hydroxide.

In addition, in the production of the cleaning compositions of Examples and Comparative Examples, all of handling of a container, and preparation, filling, storage, and analytical measurement of the cleaning composition were carried out in a clean room at a level satisfying ISO Class 2 or lower.

Furthermore, the cleaning compositions of Examples and Comparative Examples substantially did not include insoluble particles.

### <Components>

Hereinafter, each component used in the production of each cleaning composition will be described.

### [Organic Acid X]

X1: Citric acid
X2: Acetic acid
X3: Propionic acid
X4: Oxalic acid
X5: Glucuronic acid
X6: Malonic acid
X7: Succinic acid
X8: Glycolic acid
X9: Lactic acid
X10: Malic acid
X11: Tartaric acid
X12: Gluconic acid
XA1: Sorbic acid

Furthermore, the sorbic acid corresponds to the organic acid XA.

### [Organic Acid Y]

Y1: Trimellitic acid
Y2: Phthalic acid
Y3: Pyromellitic acid
Y4: Polyacrylic acid (weight-average molecular weight: 3,000)
Y5: Polyacrylic acid (weight-average molecular weight: 5,000)
Y6: Acrylic acid-methacrylic acid copolymer (molar ratio of 1:1, weight-average molecular weight: 2,000)
Y7: Acrylic acid-methacrylic acid copolymer (molar ratio 1:1, weight-average molecular weight: 5,000)
Y8: Acrylic acid-methacrylic acid copolymer (molar ratio 1:1, weight-average molecular weight: 10,000)
Y9: Polystyrene sulfonic acid (weight-average molecular weight: 2,000)
Y10: Polyacrylic acid (weight-average molecular weight: 2,000)
Y11: Sulfonic acid-acrylic acid copolymer (molar ratio of 1:1, weight-average molecular weight: 6,000)
Y12: Acrylic acid-maleic acid copolymer (molar ratio 1:1, weight-average molecular weight: 5,000)
Y13: Sulfonic acid-based copolymer (“ARON (registered trademark) A-6031” manufactured by Toagosei Co., Ltd., weight-average molecular weight: 6,000)
Y14: Polyacrylic acid-based polymer (“ARON (registered trademark) SD-10” manufactured by Toagosei Co., Ltd., weight-average molecular weight: 3,000)
Y15: Polycarboxylic acid polyalkylene glycol graft (“AQUALIC (registered trademark) PM-303B” manufactured by Nippon Shokubai Co., Ltd., weight-average molecular weight: 3,000)
YA1: Benzoic acid

Furthermore, the benzoic acid corresponds to the antibacterial aromatic organic acid A.

### [Other Organic Acids]

AA1: Cresol
AA2: Dehydroacetic acid
AA3: Catechol

Furthermore, any of other organic acids AA1 to AA3 correspond to the antibacterial organic acid A.
AA4: HEDP

### [Amino Alcohol]

A1: Trishydroxymethylaminomethane (Tris)
A2: Monoethanolamine
A3: Diethanolamine
A4: N-Methyldiethanolamine
A5: Bis(2-hydroxyethyl)aminotris(hydroxymethyl)methane (Bis-Tris)
A6: 1,3-Bis[tris(hydroxymethyl)methylamino]propane (bis-trispropane)

### [Aliphatic Hydrocarbon Amine Compound]

AO1: Ethylamine
AO2: Tetramethylethylenediamine

### [Amino Acid]

B1: L-Arginine
B2: L-Histidine
B3: L-Lysine
B4: Glycine
B5: L-Alanine
B6: L-Asparagine
B7: L-Proline
B8: L-Serine
B9: L-Methionine

### [Antimicrobial Agent]

C1: 2-Methyl-4-isothiazolin-3-one (MIT)
C2: Mixture of MIT and 2-octyl-4-isothiazolin-3-one (OIT) (weight ratio of 1:5)
C3: Polyhexamethylene biguanide (PHMB)
C4: Chlorhexidine gluconate

Furthermore, with regard to Example 57, the gluconic acid included in chlorhexidine gluconate was taken into consideration, and the amount of gluconic acid added was adjusted such that a content of gluconic acid in the cleaning composition was a value listed in the table.

Furthermore, the pH and the surface tension of each cleaning composition were measured by the above-described methods.

Moreover, with regard to the cleaning compositions of Examples 59 and 60, in a case where dodecylbenzene sulfonic acid was added such that the contents were 0.0005% by mass and 0.1% by mass, respectively with respect to the total mass of the cleaning composition, a surface tension shown in the table in the latter part was obtained.

### <Evaluations>

An Mo-containing substrate was prepared as an object to be cleaned by the following procedure.

First, a wafer in which an Mo film having a film thickness of 200 nm had been formed on a 12-inch silicon wafer by a CVD method was prepared. Next, the wafer on which the Mo film had been formed was subjected to a CMP treatment to obtain a CMP-treated substrate.

The CMP treatment of the wafer on which the Mo film had been formed was performed while supplying a slurry (FSL3400) under the following conditions, using a device “FREX300II” manufactured by Kuraray Co., Ltd. as a polishing device.
Table rotation speed: 80 rpm
Head rotation speed: 78 rpm
Polishing pressure: 120 hPa
Polishing pad: IC1400 manufactured by Rodel Nitta Company
Slurry supply rate: 250 ml/L

After the CMP treatment, an Mo-containing substrate of the object to be cleaned was obtained. The Mo-containing substrate had Mo-based residues and the region including Mo in a metallic state.

The Mo-containing substrate was subjected to single-wafer cleaning by brush scrubbing using the cleaning composition of each of Examples and Comparative Examples for 30 seconds, transported to another unit, and subjected to single-wafer cleaning by brush scrubbing using the cleaning composition for 30 seconds. Next, the Mo-containing substrate was rinsed with water for 60 seconds, and then subjected to spin drying at 1,000 rpm while spraying a surface of the Mo-containing substrate with dry nitrogen to dry the Mo-containing substrate, thereby obtaining a cleaned Mo-containing substrate 1.

The number of defects (residues) of the cleaned Mo-containing substrate 1 was confirmed by a defect inspection device (ComPlus II). In addition, the defect species were specified using a review scanning electron microscope (SEM)-energy dispersive X-ray spectroscopy (EDX), and the number of the Mo-based residues was confirmed. The residue removability was evaluated in accordance with the following evaluation standard, based on the number of the Mo-based residues.

### (Evaluation Standard for Residue Removability)

A: The number of the Mo-based residues having a size of 0.1 μm was less than 20 residues/substrate.
B: The number of the Mo-based residues having a size of 0.1 μm was 20 residues/substrate or more and less than 50 residues/substrate.
C: The number of the Mo-based residues having a size of 0.1 μm was 50 residues/substrate or more and less than 80 residues/substrate.
D: The number of the Mo-based residues having a size of 0.1 μm was 80 residues/substrate or more and less than 100 residues/substrate.
E: The number of the Mo-based residues having a size of 0.1 μm was 100 residues/substrate.

In addition, a cleaned Mo substrate 2 obtained by adding a step of performing buffing for 60 seconds using the cleaning composition of Examples and Comparative Examples before brush scrubbing cleaning in the procedure for obtaining the cleaned Mo substrate 1 was also evaluated in the same manner as for the cleaned Mo substrate 1, and the residue removability was evaluated according to the evaluation standard.

Moreover, after the cleaning, using the Mo-containing substrate, surface profiles were obtained for three points including one point of the center part and two points of the end parts of the substrate, using an atomic force microscope (AFM), and a surface roughness (Ra) was calculated. The acquisition of the surface profiles by AFM was performed in a visual field of 10 μm square. The surface roughness suppressibility was evaluated according to the following evaluation standard from the average value of the surface roughness at the three points.

### [Evaluation Standard for Surface Roughness Suppressibility]

A: The surface roughness Ra is less than 0.30 nm.
B: The surface roughness Ra is 0.30 nm or more and less than 0.35 nm.
C: The surface roughness Ra is 0.35 nm or more and less than 0.40 nm.
D: The surface roughness Ra is 0.40 nm or more and less than 0.45 nm.
E: The surface roughness Ra is 0.45 nm or more.

### <Results>

The composition of each cleaning composition and each evaluation results are shown in Tables 1 to 5.

In the tables, the columns of organic acid/organic amine compound, organic acid/amino acid, organic amine compound/antibacterial agent, and amino acid/antibacterial agent show mass ratios of each compound with respect to the total content.

In the tables, “pCMP evaluation” shows the evaluation results of the cleaned Mo substrate 1, and “Buff+pCMP evaluation” shows the evaluation results of the cleaned Mo substrate 2.

TABLE 1

| | | | | | | | Organic amine | | | | | | | |
|---|---|---|---|---|---|---|---|---|---|---|---|---|---|---|
| | | | | | | | compound | | | | | | | |
| | Organic acid | | | | | | Amino | | | | | | | |
| | | | | | Other | | alcohol or | | | | | | | |
| | Organic | | Organic | | organic | | other | | Amino | | Antibacterial | | Characteristics | |
| | acid X | | acid Y | | acids | | amines | | acid | | agent | | Surface | |
| | (% by | | (% by | | (% by | | (% by | | (% by | | (% by | | tension | |
| | mass) | | mass) | | mass) | | mass) | | mass) | | mass) | | (mN/m) | pH |
| Example 1 | X1 | 1.5 | — | — | — | — | A1 | 4.5 | B1 | 0.25 | — | — | 73 | 6 |
| Example 2 | X1 | 1.5 | — | — | — | — | A1 | 4.5 | B1 | 0.25 | — | — | 73 | 6 |
| Example 3 | X1 | 1.5 | — | — | — | — | A1 | 4.5 | B1 | 0.25 | — | — | 73 | 6 |
| Example 4 | X1 | 1.5 | — | — | — | — | A1 | 4.5 | B1 | 0.25 | — | — | 73 | 6 |
| Example 5 | X1 | 1.5 | — | — | — | — | A1 | 4.5 | B2 | 0.25 | — | — | 73 | 6 |
| Example 6 | X1 | 1.5 | — | — | — | — | A1 | 4.5 | B3 | 0.25 | — | — | 73 | 6 |
| Example 7 | X1 | 1.5 | — | — | — | — | A1 | 4.5 | B4 | 0.25 | — | — | 73 | 6 |
| Example 8 | X1 | 1.5 | — | — | — | — | A1 | 4.5 | B5 | 0.25 | — | — | 73 | 6 |
| Example 9 | X1 | 1.5 | — | — | — | — | A1 | 4.5 | B6 | 0.25 | — | — | 73 | 6 |
| Example 10 | X1 | 1.5 | — | — | — | — | A1 | 4.5 | B7 | 0.25 | — | — | 73 | 6 |
| Example 11 | X1 | 1.5 | — | — | — | — | A1 | 4.5 | B8 | 0.25 | — | — | 73 | 6 |
| Example 12 | X | 1.5 | — | — | — | — | A1 | 4.5 | B9 | 0.25 | — | — | 73 | 6 |
| Example 13 | X1 | 1.5 | — | — | — | — | A1 | 4.5 | B1 | 0.25 | — | — | 73 | 1.5 |
| Example 14 | X1 | 1.5 | — | — | — | — | A1 | 4.5 | B1 | 0.25 | — | — | 73 | 2 |
| Example 15 | X1 | 1.5 | — | — | — | — | A1 | 4.5 | B1 | 0.25 | — | — | 73 | 3 |
| Example 16 | X1 | 1.5 | — | — | — | — | A1 | 4.5 | B1 | 0.25 | — | — | 73 | 5 |
| Example 17 | X1 | 1.5 | — | — | — | — | A1 | 4.5 | B1 | 0.25 | — | — | 73 | 7 |
| Example 18 | X1 | 1.5 | — | — | — | — | A1 | 4.5 | B1 | 0.25 | — | — | 73 | 8 |
| Example 19 | X1 | 1.5 | — | — | — | — | A1 | 4.5 | B1 | 0.25 | — | — | 73 | 9 |
| Example 20 | X1 | 1.5 | — | — | — | — | A1 | 4.5 | B1 | 0.25 | — | — | 73 | 10 |
| Example 21 | X1 | 1.5 | — | — | — | — | A2 | 4.5 | B1 | 0.25 | — | — | 73 | 6 |
| Example 22 | X1 | 1.5 | — | — | — | — | A3 | 4.5 | B1 | 0.25 | — | — | 73 | 6 |
| Example 23 | X1 | 1.5 | — | — | — | — | A4 | 4.5 | B1 | 0.25 | — | — | 73 | 6 |
| Example 24 | X1 | 1.5 | — | — | — | — | A5 | 4.5 | B1 | 0.25 | — | — | 73 | 6 |
| Example 25 | X1 | 1.5 | — | — | — | — | A6 | 4.5 | B1 | 0.25 | — | — | 73 | 6 |
| Example 26 | X2 | 1.5 | — | — | — | — | A1 | 4.5 | B1 | 0.25 | — | — | 73 | 6 |
| Example 27 | X3 | 1.5 | — | — | — | — | A1 | 4.5 | B1 | 0.25 | — | — | 73 | 6 |
| Example 28 | X4 | 1.5 | — | — | — | — | A1 | 4.5 | B1 | 0.25 | — | — | 73 | 6 |
| Example 29 | X5 | 1.5 | — | — | — | — | A1 | 4.5 | B1 | 0.25 | — | — | 73 | 6 |
| Example 30 | X6 | 1.5 | — | — | — | — | A1 | 4.5 | B1 | 0.25 | — | — | 73 | 6 |
| Example 31 | X7 | 1.5 | — | — | — | — | A1 | 4.5 | B1 | 0.25 | — | — | 73 | 6 |

| | | | | | | | Buff + pCMP | |
|---|---|---|---|---|---|---|---|---|
| | Ratio (mass ratio) | | | | | | evaluation | |
| | | | Organic amine | Amino acid/ | pCMP | | | Surface |
| | Organic acid/ | | compound/ | antibacterial | evaluation | | | rough- |
| | organic amine | Organic acid/ | antibacterial | agent | | Surface | | ness |
| | compound | amino acid | agent | (mass | Residue | roughness | Residue | suppres- |
| | (mass ratio) | (mass ratio) | (mass ratio) | ratio) | removability | suppressibility | removability | sibility |
| Example 1 | 0.32 | 6.0 | — | — | B | A | A | A |
| Example 2 | 0.32 | 6.0 | — | — | A | A | A | A |
| Example 3 | 0.32 | 6.0 | — | — | A | A | A | A |
| Example 4 | 0.32 | 6.0 | — | — | A | A | A | A |
| Example 5 | 0.32 | 6.0 | — | — | B | A | A | A |
| Example 6 | 0.32 | 6.0 | — | — | B | A | A | A |
| Example 7 | 0.32 | 6.0 | — | — | B | B | A | B |
| Example 8 | 0.32 | 6.0 | — | — | B | B | A | B |
| Example 9 | 0.32 | 6.0 | — | — | B | B | A | B |
| Example 10 | 0.32 | 6.0 | — | — | B | B | A | B |
| Example 11 | 0.32 | 6.0 | — | — | B | B | A | B |
| Example 12 | 0.32 | 6.0 | — | — | B | B | A | B |
| Example 13 | 0.32 | 6.0 | — | — | D | B | C | B |
| Example 14 | 0.32 | 6.0 | — | — | C | A | B | A |
| Example 15 | 0.32 | 6.0 | — | — | B | A | A | A |
| Example 16 | 0.32 | 6.0 | — | — | B | A | A | A |
| Example 17 | 0.32 | 6.0 | — | — | B | A | A | A |
| Example 18 | 0.32 | 6.0 | — | — | B | A | A | A |
| Example 19 | 0.32 | 6.0 | — | — | A | B | A | B |
| Example 20 | 0.32 | 6.0 | — | — | A | D | A | D |
| Example 21 | 0.32 | 6.0 | — | — | B | B | A | B |
| Example 22 | 0.32 | 6.0 | — | — | B | B | A | B |
| Example 23 | 0.32 | 6.0 | — | — | B | B | A | B |
| Example 24 | 0.32 | 6.0 | — | — | B | A | A | A |
| Example 25 | 0.32 | 6.0 | — | — | B | A | A | A |
| Example 26 | 0.32 | 6.0 | — | — | C | A | B | A |
| Example 27 | 0.32 | 6.0 | — | — | B | A | A | A |
| Example 28 | 0.32 | 6.0 | — | — | B | A | A | A |
| Example 29 | 0.32 | 6.0 | — | — | B | A | A | A |
| Example 30 | 0.32 | 6.0 | — | — | B | A | A | A |
| Example 31 | 0.32 | 6.0 | — | — | B | A | A | A |

TABLE 2

| | | | | | | | Organic amine | | | | | | | |
|---|---|---|---|---|---|---|---|---|---|---|---|---|---|---|
| | | | | | | | compound | | | | | | | |
| | Organic acid | | | | | | Amino | | | | | | | |
| | | | | | Other | | alcohol or | | | | | | | |
| | Organic | | Organic | | organic | | other | | Amino | | Antibacterial | | Characteristics | |
| | acid X | | acid Y | | acids | | amines | | acid | | agent | | Surface | |
| | (% by | | (% by | | (% by | | (% by | | (% by | | (% by | | tension | |
| | mass) | | mass) | | mass) | | mass) | | mass) | | mass) | | (mN/m) | pH |
| Example 32 | X8 | 1.5 | — | — | — | — | A1 | 4.5 | B1 | 0.25 | — | — | 73 | 6 |
| Example 33 | X9 | 1.5 | — | — | — | — | A1 | 4.5 | B1 | 0.25 | — | — | 73 | 6 |
| Example 34 | X10 | 1.5 | — | — | — | — | A1 | 4.5 | B1 | 0.25 | — | — | 73 | 6 |
| Example 35 | X11 | 1.5 | — | — | — | — | A1 | 4.5 | B1 | 0.25 | — | — | 73 | 6 |
| Example 36 | X12 | 1.5 | — | — | — | — | A1 | 4.5 | B1 | 0.25 | — | — | 73 | 6 |
| Example 37 | X1 | 1.5 | Y1 | 0.1 | — | — | A1 | 4.5 | B1 | 0.25 | — | — | 73 | 6 |
| Example 38 | X1 | 1.5 | Y1 | 0.1 | — | — | A1 | 2.25 | — | — | — | — | 73 | 6 |
| | | | | | | | A2 | 2.25 | | | | | | |
| Example 39 | X1 | 1.5 | Y1 | 0.1 | — | — | AO1 | 2.25 | — | — | — | — | 73 | 6 |
| | | | | | | | AO2 | 2.25 | | | | | | |
| Example 40 | X1 | 1.5 | Y1 | 0.1 | — | — | — | — | B1 | 0.125 | — | — | 73 | 6 |
| | | | | | | | | | B2 | 0.125 | | | | |
| Example 41 | X1 | 1.5 | Y2 | 0.1 | — | — | A1 | 4.5 | B1 | 0.25 | — | — | 73 | 6 |
| Example 42 | X1 | 1.5 | Y3 | 0.1 | — | — | A1 | 4.5 | B1 | 0.25 | — | — | 73 | 6 |
| Example 43 | | 1.5 | Y4 | 0.1 | — | — | A1 | 4.5 | B1 | 0.25 | — | — | 73 | 6 |
| Example 44 | X1 | 1.5 | Y5 | 0.1 | — | — | A1 | 4.5 | B1 | 0.25 | — | — | 73 | 6 |
| Example 45 | X1 | 1.5 | Y6 | 0.1 | — | — | A1 | 4.5 | B1 | 0.25 | — | — | 73 | 6 |
| Example 46 | X1 | 1.5 | Y7 | 0.1 | — | — | A1 | 4.5 | B1 | 0.25 | — | — | 73 | 6 |
| Example 47 | X1 | 1.5 | Y8 | 0.1 | — | — | A1 | 4.5 | B1 | 0.25 | — | — | 73 | 6 |
| Example 48 | X1 | 1.5 | Y9 | 0.1 | — | — | A1 | 4.5 | B1 | 0.25 | — | — | 73 | 6 |
| Example 49 | X1 | 1.5 | Y1 | 0.1 | — | — | A1 | 4.5 | B1 | 0.25 | — | — | 73 | 6 |
| | XA1 | 0.05 | | | | | | | | | | | | |
| Example 50 | X1 | 1.5 | Y1 | 0.1 | — | — | A1 | 4.5 | B1 | 0.25 | C1 | 0.05 | 73 | 6 |
| Example 51 | X1 | 1.5 | Y1 | 0.1 | — | — | A1 | 4.5 | B1 | 0.25 | C2 | 0.05 | 73 | 6 |
| Example 52 | X1 | 1.5 | Y1 | 0.1 | AA1 | 0.05 | A1 | 4.5 | B1 | 0.25 | — | — | 73 | 6 |
| Example 53 | X1 | 1.5 | Y1 | 0.1 | AA2 | 0.05 | A1 | 4.5 | B1 | 0.25 | — | — | 73 | 6 |
| | | 0.05 | | | | | | | | | | | | |
| Example 54 | X1 | 1.5 | Y1 | 0.1 | — | — | A1 | 4.5 | B1 | 0.25 | — | — | 73 | 6 |
| | | 0.05 | YA1 | 0.05 | | | | | | | | | | |

Buff + pCMP

| | |
|---|---|
| Ratio (mass ratio) | evaluation |

| | | | Organic amine | Amino acid/ | pCMP | | | Surface |
|---|---|---|---|---|---|---|---|---|
| | Organic acid/ | | compound/ | antibacterial | evaluation | | | rough- |
| | organic amine | Organic acid/ | antibacterial | agent | | Surface | | ness |
| | compound | amino acid | agent | (mass | Residue | roughness | Residue | suppres- |
| | (mass ratio) | (mass ratio) | (mass ratio) | ratio) | removability | suppressibility | removability | sibility |
| Example 32 | 0.32 | 6.0 | — | — | B | A | A | A |
| Example 33 | 0.32 | 6.0 | — | — | B | A | A | A |
| Example 34 | 0.32 | 6.0 | — | — | B | A | A | A |
| Example 35 | 0.32 | 6.0 | — | — | B | A | A | A |
| Example 36 | 0.32 | 6.0 | — | — | B | A | A | A |
| Example 37 | 0.34 | 6.4 | — | — | A | A | A | A |
| Example 38 | 0.34 | — | — | — | A | B | A | B |
| Example 39 | 0.34 | — | — | — | B | B | A | B |
| Example 40 | 0.34 | 6.4 | — | — | B | A | A | A |
| Example 41 | 0.34 | 6.4 | — | — | A | A | A | A |
| Example 42 | 0.34 | 6.4 | — | — | A | A | A | A |
| Example 43 | 0.34 | 6.4 | — | — | A | A | A | A |
| Example 44 | 0.34 | 6.4 | — | — | A | A | A | A |
| Example 45 | 0.34 | 6.4 | — | — | A | A | A | A |
| Example 46 | 0.34 | 6.4 | — | — | A | A | A | A |
| Example 47 | 0.34 | 6.4 | — | — | B | A | A | A |
| Example 48 | 0.34 | 6.4 | — | — | A | A | A | A |
| Example 49 | 0.35 | 6.5 | — | — | A | A | A | A |
| Example 50 | 0.34 | 6.4 | 95.0 | 5.0 | A | A | A | A |
| Example 51 | 0.34 | 6.4 | 95.0 | 5.0 | A | A | A | A |
| Example 52 | 0.33 | 6.6 | — | — | A | A | A | A |
| Example 53 | 0.36 | 6.8 | — | — | A | A | A | A |
| Example 54 | 0.36 | 6.8 | — | — | A | A | A | A |

TABLE 3

| | | | | | | | Organic amine | | | | | | | |
|---|---|---|---|---|---|---|---|---|---|---|---|---|---|---|
| | | | | | | | compound | | | | | | | |
| | Organic acid | | | | | | Amino | | | | | | | |
| | | | | | Other | | alcohol or | | | | Anti- | | | |
| | Organic | | Organic | | organic | | other | | Amino | | bacterial | | Characteristics | |
| | acid X | | acid Y | | acids | | amines | | acid | | agent | | Surface | |
| | (% by | | (% by | | (% by | | (% by | | (% by | | (% by | | tension | |
| | mass) | | mass) | | mass) | | mass) | | mass) | | mass) | | (mN/m) | pH |
| Example 55 | X1 | 1.5 | Y1 | 0.1 | AA3 | 0.05 | A1 | 4.5 | B1 | 0.25 | — | — | 73 | 6 |
| Example 56 | X1 | 1.5 | Y1 | 0.1 | — | — | A1 | 4.5 | B1 | 0.25 | C3 | 0.05 | 73 | 6 |
| Example 57 | X12 | 1.5 | Y1 | 0.1 | — | — | A1 | 4.5 | B1 | 0.25 | C4 | 0.05 | 73 | 6 |
| Example 58 | X1 | 0.25 | Y1 | 0.1 | — | — | A1 | 4.5 | B1 | 0.25 | C1 | 0.05 | 73 | 6 |
| | XA1 | 0.05 | | | | | | | | | | | | |
| Example 59 | X1 | 0.25 | Y1 | 0.1 | — | — | A1 | 4.5 | B1 | 0.25 | C1 | 0.05 | 64 | 6 |
| | XA1 | 0.05 | | | | | | | | | | | | |
| Example 60 | X1 | 0.25 | Y1 | 0.1 | — | — | A1 | 4.5 | B1 | 0.25 | C1 | 0.05 | 32 | 6 |
| | XA1 | 0.05 | | | | | | | | | | | | |
| Example 61 | X1 | 0.40 | Y1 | 0.1 | — | — | A1 | 4.5 | B1 | 0.25 | C1 | 0.05 | 73 | 6 |
| | XA1 | 0.05 | | | | | | | | | | | | |
| Example 62 | X1 | 1.5 | Y1 | 0.1 | — | — | A1 | 4.5 | B1 | 0.25 | C1 | 0.05 | 73 | 6 |
| | XA1 | 0.05 | | | | | | | | | | | | |
| Example 63 | X1 | 1.5 | Y1 | 0.1 | — | — | A1 | 1.0 | B1 | 0.25 | C1 | 0.05 | 73 | 6 |
| | XA1 | 0.05 | | | | | | | | | | | | |
| Example 64 | X1 | 1.5 | Y1 | 0.1 | — | — | A1 | 0.3 | B1 | 0.25 | C1 | 0.05 | 73 | 6 |
| | XA1 | 0.05 | | | | | | | | | | | | |
| Example 65 | X1 | 1.5 | Y1 | 0.1 | — | — | A1 | 0.03 | B1 | 0.25 | C1 | 0.05 | 73 | 6 |
| | XA1 | 0.05 | | | | | | | | | | | | |
| Example 66 | X1 | 1.5 | Y1 | 0.1 | — | — | A1 | 0.02 | B1 | 0.25 | C1 | 0.05 | 73 | 6 |
| | XA1 | 0.05 | | | | | | | | | | | | |
| Example 67 | X1 | 1.5 | Y1 | 0.1 | — | — | A1 | 4.5 | B1 | 5.0 | C1 | 0.05 | 73 | 6 |
| | XA1 | 0.05 | | | | | | | | | | | | |
| Example 68 | X1 | 1.5 | Y1 | 0.1 | — | — | A1 | 4.5 | B1 | 0.5 | C1 | 0.05 | 73 | 6 |
| | XA1 | 0.05 | | | | | | | | | | | | |
| Example 69 | X1 | 1.5 | Y1 | 0.1 | — | — | A1 | 4.5 | B1 | 0.03 | C1 | 0.05 | 73 | 6 |
| | XA1 | 0.05 | | | | | | | | | | | | |
| Example 70 | X1 | 4.95 | Y1 | 0.1 | — | — | A1 | 4.5 | B1 | 0.025 | C1 | 0.05 | 73 | 6 |
| | XA1 | 0.05 | | | | | | | | | | | | |
| Example 71 | X1 | 4.95 | Y1 | 0.1 | — | — | A1 | 4.5 | B1 | 0.02 | C1 | 0.05 | 73 | 6 |
| | XA1 | 0.05 | | | | | | | | | | | | |
| Comparative | X1 | 1.5 | — | — | — | — | A1 | 4.5 | — | — | — | — | 73 | 6 |
| Example 1 | | | | | | | | | | | | | | |

Buff + pCMP

| | |
|---|---|
| Ratio (mass ratio) | evaluation |

| | Organic | Organic | Organic amine | Amino acid/ | pCMP | | | Surface |
|---|---|---|---|---|---|---|---|---|
| | acid/ organic | acid/ | compound/ | antibacterial | evaluation | | | rough- |
| | amine | amino acid | antibacterial | agent | | Surface | Residue | ness |
| | compound | (mass | agent | (mass | Residue | roughness | remo- | suppres- |
| | (mass ratio) | ratio) | (mass ratio) | ratio) | removability | suppressibility | vability | sibility |
| Example 55 | 0.35 | 6.6 | 95.0 | 5.0 | A | A | A | A |
| Example 56 | 0.34 | 6.4 | 95.0 | 5.0 | A | A | A | A |
| Example 57 | 0.34 | 6.4 | 95.0 | 5.0 | A | A | A | A |
| Example 58 | 0.08 | 1.6 | 95.0 | 5.0 | B | A | A | A |
| Example 59 | 0.08 | 1.6 | 95.0 | 5.0 | B | B | A | B |
| Example 60 | 0.11 | 2.0 | 95.0 | 5.0 | C | B | B | B |
| Example 61 | 0.12 | 2.2 | 95.0 | 5.0 | A | A | A | A |
| Example 62 | 0.35 | 6.6 | 95.0 | 5.0 | A | A | A | A |
| Example 63 | 1.32 | 6.6 | 25.0 | 5.0 | A | A | A | A |
| Example 64 | 3.00 | 6.6 | 11.0 | 5.0 | A | A | A | A |
| Example 65 | 5.89 | 6.6 | 5.6 | 5.0 | A | A | A | A |
| Example 66 | 6.11 | 6.6 | 5.4 | 5.0 | A | A | A | A |
| Example 67 | 0.17 | 0.3 | 190.0 | 100.0 | C | A | B | A |
| Example 68 | 0.33 | 3.3 | 100.0 | 10.0 | B | A | A | A |
| Example 69 | 0.36 | 55.0 | 90.6 | 0.6 | A | A | A | A |
| Example 70 | 1.13 | 204.0 | 90.5 | 0.5 | A | B | A | B |
| Example 71 | 1.13 | 255.0 | 90.4 | 0.4 | A | A | A | C |
| Comparative | — | — | — | — | C | E | B | E |
| Example 1 | | | | | | | | |

TABLE 4

| | | | | | | | Organic amine | | | | | | | |
|---|---|---|---|---|---|---|---|---|---|---|---|---|---|---|
| | | | | | | | compound | | | | | | | |
| | Organic acid | | | | | | Amino | | | | | | | |
| | | | | | Other | | alcohol or | | | | | | | |
| | Organic | | Organic | | organic | | other | | Amino | | Antibacterial | | Characteristics | |
| | acid X | | acid Y | | acids | | amines | | acid | | agent | | Surface | |
| | (% by | | (% by | | (% by | | (% by | | (% by | | (% by | | tension | |
| | mass) | | mass) | | mass) | | mass) | | mass) | | mass) | | (mN/m) | pH |
| Example 72 | X1 | 0.30 | Y5 | 0.1 | AA4 | 0.1 | A1 | 0.5 | B1 | 1 | — | — | 73 | 6 |
| | XA1 | 0.05 | | | | | | | | | | | | |
| Example 73 | X1 | 0.30 | Y5 | 0.1 | AA4 | 0.1 | A1 | 0.5 | B1 | 1 | — | — | 73 | 7 |
| | XA1 | 0.05 | | | | | | | | | | | | |
| Example 74 | X1 | 0.30 | Y5 | 0.1 | AA4 | 0.1 | A1 | 0.5 | B1 | 1 | — | — | 73 | 8 |
| | XA1 | 0.05 | | | | | | | | | | | | |
| Example 75 | X1 | 0.30 | Y1 | 0.1 | — | — | A1 | 0.5 | B1 | 0.25 | — | — | 73 | 6 |
| | XA1 | 0.05 | | | | | | | | | | | | |
| Example 76 | X1 | 0.3 | Y1 | 0.1 | — | — | A1 | 2.0 | B1 | 0.25 | — | — | 73 | 6 |
| | XA1 | 0.05 | Y11 | 1.5 | | | | | | | | | | |
| Example 77 | X1 | 0.90 | Y1 | 0.1 | — | — | A1 | 2.0 | B1 | 0.25 | C1 | 0.05 | 73 | 6 |
| | XA1 | 0.05 | Y11 | 1.5 | | | | | | | | | | |
| Example 78 | X1 | 0.90 | Y1 | 0.1 | — | — | A1 | 2.0 | B1 | 0.25 | — | — | 73 | 6 |
| | X13 | 0.40 | | | | | | | | | | | | |
| | XA1 | 0.05 | | | | | | | | | | | | |
| Example 79 | X1 | 0.90 | Y1 | 0.1 | AA4 | 0.1 | A1 | 4.5 | B1 | 0.25 | — | — | 73 | 6 |
| | XA1 | 0.05 | Y11 | 1.5 | | | | | | | | | | |
| Example 80 | X1 | 0.90 | Y1 | 0.1 | AA4 | 0.1 | A1 | 4.5 | B1 | 0.25 | C1 | 0.05 | 73 | 6 |
| | XA1 | 0.05 | Y11 | 1.5 | | | | | | | | | | |
| Example 81 | X1 | 0.3 | Y1 | 0.1 | — | — | A1 | 2.0 | B1 | 0.25 | — | — | 73 | 6 |
| | XA1 | 0.05 | Y5 | 1.5 | | | | | | | | | | |

| | | | | | | | Buff + pCMP | |
|---|---|---|---|---|---|---|---|---|
| | Ratio (mass ratio) | | | | | | evaluation | |
| | Organic acid/ | Organic | Organic amine | Amino acid/ | pCMP | | | Surface |
| | organic | acid/ | compound/ | antibacterial | evaluation | | | rough- |
| | amine | amino acid | antibacterial | agent | | Surface | | ness |
| | compound | (mass | agent | (mass | Residue | roughness | Residue | suppres- |
| | (mass ratio) | ratio) | (mass ratio) | ratio) | removability | suppressibility | removability | sibility |
| Example 72 | 0.4 | 0.6 | — | — | B | A | A | A |
| Example 73 | 0.37 | 0.6 | — | — | B | A | A | A |
| Example 74 | 0.37 | 0.6 | — | — | B | A | A | A |
| Example 75 | 0.60 | 1.8 | — | — | B | A | A | A |
| Example 76 | 0.87 | 7.8 | — | — | A | A | A | A |
| Example 77 | 1.13 | 10.2 | 45.0 | 5.0 | A | A | A | A |
| Example 78 | 0.64 | 5.8 | — | — | A | A | A | A |
| Example 79 | 0.62 | 11.8 | — | — | A | A | A | A |
| Example 80 | 0.62 | 11.8 | 95.0 | 5.0 | A | A | A | A |
| Example 81 | 0.87 | 7.8 | — | — | A | A | A | A |

TABLE 5

| | | | | | | | Organic amine | | | | | | | |
|---|---|---|---|---|---|---|---|---|---|---|---|---|---|---|
| | | | | | | | compound | | | | | | | |
| | Organic acid | | | | | | Amino | | | | | | | |
| | | | | | Other | | alcohol or | | | | | | | |
| | Organic | | Organic | | organic | | other | | Amino | | Antibacterial | | Characteristics | |
| | acid X | | acid Y | | acids | | amines | | acid | | agent | | Surface | |
| | (% by | | (% by | | (% by | | (% by | | (% by | | (% by | | tension | |
| | mass) | | mass) | | mass) | | mass) | | mass) | | mass) | | (mN/m) | pH |
| Example 82 | X1 | 0.3 | Y1 | 0.1 | — | — | A1 | 2.0 | B1 | 0.25 | — | — | 73 | 6 |
| | XA1 | 0.05 | Y10 | 1.5 | | | | | | | | | | |
| Example 83 | X1 | 0.3 | Y1 | 0.1 | — | — | A1 | 2.0 | B1 | 0.25 | — | — | 73 | 6 |
| | XA1 | 0.05 | Y12 | 1.5 | | | | | | | | | | |
| Example 84 | X1 | 0.3 | Y1 | 0.1 | — | — | A1 | 2.0 | B1 | 0.25 | — | — | 73 | 6 |
| | XA1 | 0.05 | Y13 | 1.5 | | | | | | | | | | |
| Example 85 | X1 | 0.3 | Y1 | 0.1 | — | — | A1 | 2.0 | B1 | 0.25 | — | — | 73 | 6 |
| | XA1 | 0.05 | Y14 | 1.5 | | | | | | | | | | |
| Example 86 | X1 | 0.3 | Y1 | 0.1 | — | — | A1 | 2.0 | B1 | 0.25 | — | — | 73 | 6 |
| | XA1 | 0.05 | Y15 | 1.5 | | | | | | | | | | |
| Example 87 | X1 | 0.3 | Y5 | 1.5 | — | — | A1 | 0.5 | B1 | 0.25 | — | — | 73 | 6 |
| | XA1 | 0.05 | | | | | | | | | | | | |
| Example 88 | X1 | 0.3 | Y10 | 0.1 | — | — | A1 | 0.5 | B1 | 0.25 | C1 | 0.05 | 73 | 6 |
| | XA1 | 0.05 | | | | | | | | | | | | |
| Example 89 | X1 | 0.3 | Y11 | 0.1 | — | — | A1 | 0.5 | B1 | 0.25 | C1 | 0.05 | 73 | 6 |
| | XA1 | 0.05 | | | | | | | | | | | | |
| Example 90 | X1 | 0.3 | Y12 | 0.1 | — | — | A1 | 0.5 | B1 | 0.25 | C1 | 0.05 | 73 | 6 |
| | XA1 | 0.05 | | | | | | | | | | | | |
| Example 91 | XI | 0.3 | Y13 | 0.1 | — | — | A1 | 0.5 | B1 | 0.25 | C1 | 0.05 | 73 | 6 |
| | XA1 | 0.05 | | | | | | | | | | | | |
| Example 92 | X1 | 0.3 | Y14 | 0.1 | — | — | A1 | 0.5 | B1 | 0.25 | C1 | 0.05 | 73 | 6 |
| | XA1 | 0.05 | | | | | | | | | | | | |
| Example 93 | X1 | 0.3 | Y15 | 0.1 | — | — | A1 | 0.5 | B1 | 0.25 | C1 | 0.05 | 73 | 6 |
| | XA1 | 0.05 | | | | | | | | | | | | |

Buff + pCMP

| | |
|---|---|
| Ratio (mass ratio) | evaluation |

| | | | Organic amine | Amino acid/ | pCMP | | | Surface |
|---|---|---|---|---|---|---|---|---|
| | Organic acid/ | | compound/ | antibacterial | evaluation | | | rough- |
| | organic amine | Organic acid/ | antibacterial | agent | | Surface | | ness |
| | compound | amino acid | agent | (mass | Residue | roughness | Residue | suppres- |
| | (mass ratio) | (mass ratio) | (mass ratio) | ratio) | removability | suppressibility | removability | sibility |
| Example 82 | 0.87 | 7.8 | — | — | A | A | A | A |
| Example 83 | 0.87 | 7.8 | — | — | A | A | A | A |
| Example 84 | 0.87 | 7.8 | — | — | A | A | A | A |
| Example 85 | 0.87 | 7.8 | — | — | A | A | A | A |
| Example 86 | 0.87 | 7.8 | — | — | A | A | A | A |
| Example 87 | 2.47 | 7.4 | — | — | A | A | A | A |
| Example 88 | 0.60 | 1.8 | 15.0 | 5.0 | B | A | A | A |
| Example 89 | 0.60 | 1.8 | 15.0 | 5.0 | B | A | A | A |
| Example 90 | 0.60 | 1.8 | 15.0 | 5.0 | B | A | A | A |
| Example 91 | 0.60 | 1.8 | 15.0 | 5.0 | B | A | A | A |
| Example 92 | 0.60 | 1.8 | 15.0 | 5.0 | B | A | A | A |
| Example 93 | 0.60 | 1.8 | 15.0 | 5.0 | B | A | A | A |

From the results in Tables 1 to 5, it was confirmed that the cleaning compositions of Examples, which include the organic acid and two kinds of the organic amine compounds, have excellent removability of residues and can suppress the surface roughness. On the other hand, in the cleaning composition of Comparative Example 1, which includes only one kind of organic amine compound, the surface roughness could not be suppressed.

From the comparison between Examples 14 to 19 and Examples 13 and 20, it was confirmed that in a case where the pH is 2 to 9, at least one of an effect that the removability of residues is more excellent or an effect that the surface roughness can be further suppressed is satisfied.

From the comparison between Examples 15 to 18 and Examples 14 and 19, it was confirmed that in a case where the pH is 3 to 8, at least one of an effect that the removability of residues is more excellent or an effect that the surface roughness can be further suppressed is satisfied.

From the comparison between Example 38 and Examples 39 and 40, it was confirmed that in a case where two or more kinds of organic amine compounds include an amino alcohol, the removability of residues is more excellent.

From the comparison between Example 40 and Examples 38 and 39, it was confirmed that in a case where two or more kinds of organic amine compounds include an amino acid, the surface roughness can be further suppressed.

From the comparison between Examples 68 to 70 and Examples 67 and 71, it was confirmed that in a case where a mass ratio of the content of the organic acid to the content of the amino acid is 2.0 to 210, at least one of an effect that the removability of residues is more excellent or an effect that the surface roughness can be further suppressed is satisfied.

From the comparison between Example 1 and Example 37, it was confirmed that in a case where two or more kinds of organic acids are included, the removability of residues is more excellent.

From the comparison between Examples 1 and 27 to 36 and Example 26, it was confirmed that in a case where the organic acid X includes one or more selected from the group consisting of propionic acid, oxalic acid, malonic acid, succinic acid, adipic acid, gluconic acid, glycolic acid, lactic acid, malic acid, tartaric acid, citric acid, and gluconic acid, the removability of residues is more excellent.

From the comparison between Examples 37 and 41 to 48, and Example 1, it was confirmed that in a case where one or more kinds of organic acids Y selected from the group consisting of the compound represented by Formula (Y1) and the high-molecular-weight compound having an acid group are included, the removability of residues is more excellent.

From the comparison between Examples 41 and 42, and Example 43, it was confirmed that in a case where the molecular weight of the organic acid is 5,000 or less, the removability of residues is more excellent.

From the comparison between Examples 61 to 66 and Example 58, it was confirmed that in a case where a mass ratio of the content of the organic acid to the total content of the organic amine compounds is 0.10 to 6.20, the removability of residues is more excellent.

From the comparison between Example 58 and Examples 59 and 60, it was confirmed that in a case where the surface tension is 65 to 75 mN/m, at least one of an effect that the removability of residues is more excellent or an effect that the surface roughness can be further suppressed is satisfied.

What is claimed is:

1. A cleaning composition used in a treatment of a molybdenum-containing substrate, the cleaning composition comprising:
an organic acid; and
organic amine compounds having at least one group selected from the group consisting of a primary amino group, a secondary amino group, and a tertiary amino group,
wherein the cleaning composition includes two or more kinds of the organic amine compounds.

2. The cleaning composition according to claim 1,
wherein the cleaning composition has a pH of 2 to 9.

3. The cleaning composition according to claim 1,
wherein the cleaning composition has a pH of 3 to 8.

4. The cleaning composition according to claim 1,
wherein the two or more kinds of the organic amine compounds include an amino alcohol.

5. The cleaning composition according to claim 1,
wherein the two or more kinds of the organic amine compounds include an amino acid.

6. The cleaning composition according to claim 5,
wherein a mass ratio of a content of the organic acid to a content of the amino acid is 2.0 to 210.0.

7. The cleaning composition according to claim 1,
wherein the cleaning composition includes two or more kinds of the organic acids.

8. The cleaning composition according to claim 1,
wherein the organic acid includes one or more kinds of organic acids X selected from the group consisting of an aliphatic monocarboxylic acid, an aliphatic polycarboxylic acid, and an aliphatic hydroxycarboxylic acid.

9. The cleaning composition according to claim 8,
wherein the organic acids X include one or more kinds of compounds selected from the group consisting of propionic acid, oxalic acid, malonic acid, succinic acid, adipic acid, glucuronic acid, glycolic acid, lactic acid, malic acid, tartaric acid, citric acid, and gluconic acid.

10. The cleaning composition described in claim 1,
wherein the organic acid includes one or more kinds of organic acids Y selected from the group consisting of a compound represented by Formula (Y1) and a high-molecular-weight compound having an acid group, 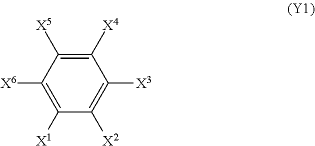
in Formula (Y1), X¹ represents an acid group, and
X² to X⁶ each independently represent a hydrogen atom or a substituent, and at least one of X², . . . , or X⁶ represents a hydrophilic group.

11. The cleaning composition according to claim 1,
wherein the organic acid has a molecular weight of 5,000 or less.

12. The cleaning composition according to claim 1,
wherein a mass ratio of a content of the organic acid to a total content of the organic amine compounds is 0.10 to 6.20.

13. The cleaning composition according to claim 1, further comprising:
an antibacterial agent.

14. The cleaning composition according to claim 13,
wherein a mass ratio of a total content of the organic amine compounds to a content of the antibacterial agent is 0.1 to 200.0.

15. The cleaning composition according to claim 13,
wherein the organic amine compounds include an amino acid, and
a mass ratio of a content of the amino acid to a content of the antibacterial agent is 0.1 to 200.0.

16. The cleaning composition according to claim 1,
wherein the cleaning composition has a surface tension of 65 to 75 mN/m.

17. The cleaning composition according to claim 1,
wherein the cleaning composition is used in a treatment of the molybdenum-containing substrate which has been subjected to a chemical mechanical polishing treatment.

18. The cleaning composition according to claim 1,
wherein the molybdenum-containing substrate further includes a material selected from the group consisting of silicon, silicon nitride, silicon oxide, silicon oxynitride, carbon-containing silicon oxide, and silicon carbide.

19. The cleaning composition according to claim 2,
wherein the two or more kinds of the organic amine compounds include an amino alcohol.

20. A method for manufacturing a semiconductor substrate, comprising:
a step of cleaning a molybdenum-containing substrate, using the cleaning composition according to claim 1.
